(19) United States
(12) Patent Application Publication
(10) Pub. No.: US 2025/0293221 A1
(43) Pub. Date: Sep. 18, 2025

(54) ELECTRONIC DEVICE

(71) Applicant: Advanced Semiconductor Engineering, Inc., Kaohsiung (TW)

(72) Inventors: Wei-Hao CHANG, Kaohsiung (TW); Yi Chun CHOU, Kaohsiung (TW)

(73) Assignee: Advanced Semiconductor Engineering, Inc., Kaohsiung (TW)

(21) Appl. No.: 18/605,711

(22) Filed: Mar. 14, 2024

(51) Int. Cl. H01L 25/16; H01L 21/48; H01L 21/56; H01L 23/29; H01L 23/31; H01L 23/495; H01L 23/66

(52) U.S. Cl. CPC H01L 25/165; H01L 21/4825; H01L 21/565; H01L 23/293; H01L 23/3135; H01L 23/4952; H01L 23/49593; H01L 23/66; H01L 25/162; H01L 2223/6677

(57) ABSTRACT

The present disclosure provides an electronic device and a method of manufacturing the same. The electronic device includes a pliable encapsulant, a first electronic component, and a first conductive connection. The pliable encapsulant has a first predetermined pattern. The first electronic component includes a terminal exposed by the first predetermined pattern. The first conductive connection is disposed within the first predetermined pattern and electrically connected to the terminal of the first electronic component.

### BACKGROUND

### 1. Field of the Disclosure

The present disclosure generally relates to an electronic device, in particular to an electronic device including a predetermined pattern configured to accommodate conductive traces.

### 2. Description of the Related Art

Flexible packaging materials are becoming increasingly popular and can be applied to wearable electronic devices. Stretchable system in package (SiP) has been recently used in electronic devices. However, the above-mentioned electronic devices encounter the following problems. First, currently, polyimide (PI) is used as the substrate, which is flexible but not stretchable. In addition, previous products involved the combination of flexible substrate and flexible films, which involved the bonding of heterogeneous materials and carried the risk of delamination due to differences in thermal expansion coefficients (CTE). Therefore, a new electronic device is required.

### SUMMARY

In some arrangements, an electronic device includes a pliable encapsulant, a first electronic component, and a first conductive connection. The pliable encapsulant has a first predetermined pattern. The first electronic component includes a terminal exposed by the first predetermined pattern. The first conductive connection is disposed within the first predetermined pattern and electrically connected to the terminal of the first electronic component.

In some arrangements, an electronic device includes a pliable encapsulant, a first conductive connection, and a second conductive connection. The pliable encapsulant has an upper surface and a lower surface. The first conductive connection is recessed from the lower surface. The second conductive connection is recessed from the upper surface and electrically connected to the first conductive connection.

In some arrangements, a method of manufacturing an electronic device includes: providing a first electronic component and an encapsulant encapsulating the first electronic component; forming a first predetermined pattern defined by the encapsulant; and forming a first conductive connection within the first predetermined pattern of the encapsulant to be electrically connected to the first electronic component.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1 is a cross-sectional view of an electronic device, in accordance with an arrangement of the present disclosure.

FIG. 2 is a cross-sectional view of an electronic component, in accordance with an arrangement of the present disclosure.

FIG. 3A is a cross-sectional view of an electronic device, in accordance with an arrangement of the present disclosure.

FIG. 3B is a cross-sectional view of an electronic device, in accordance with an arrangement of the present disclosure.

FIG. 4A is a partial enlarged view of the electronic device as shown in FIG. 3A, in accordance with an arrangement of the present disclosure.

FIG. 4B is a partial enlarged view of the electronic device as shown in FIG. 3A, in accordance with an arrangement of the present disclosure.

FIG. 4C is a partial enlarged view of the electronic device as shown in FIG. 3A, in accordance with an arrangement of the present disclosure.

FIG. 5A is a partial enlarged view of the electronic device as shown in FIG. 3A, in accordance with an arrangement of the present disclosure.

FIG. 5B is a partial enlarged view of the electronic device as shown in FIG. 3A, in accordance with an arrangement of the present disclosure.

FIG. 6A is a bottom view of a layout of an electronic device, in accordance with an arrangement of the present disclosure.

FIG. 6B is a partial enlarged view of the electronic device as shown in FIG. 6A, in accordance with an arrangement of the present disclosure.

FIG. 7A is a cross-sectional view of an electronic component, in accordance with an arrangement of the present disclosure.

FIG. 7B is a partial enlarged view of the electronic device as shown in FIG. 7A, in accordance with an arrangement of the present disclosure.

FIG. 8 is a cross-sectional view of an electronic device, in accordance with an arrangement of the present disclosure.

FIG. 9 is a cross-sectional view of an electronic device, in accordance with an arrangement of the present disclosure.

FIG. 10 is a cross-sectional view of an electronic device, in accordance with an arrangement of the present disclosure.

FIG. 11 is a cross-sectional view of an electronic device, in accordance with an arrangement of the present disclosure.

FIG. 12A, FIG. 12B, FIG. 12C, and FIG. 12D illustrate one or more stages of an example of a method for manufacturing an electronic device according to some arrangements of the present disclosure.

FIG. 13A, FIG. 13B, and FIG. 13C illustrate one or more stages of an example of a method for manufacturing an electronic device according to some arrangements of the present disclosure.

FIG. 14A is a partial enlarged view of the stage as shown in FIG. 13A, in accordance with an arrangement of the present disclosure.

FIG. 14B is a partial enlarged view of the stage as shown in FIG. 13A, in accordance with an arrangement of the present disclosure.

FIG. 14C is a partial enlarged view of the stage as shown in FIG. 13A, in accordance with an arrangement of the present disclosure.

FIG. 15A, FIG. 15B, FIG. 15C, FIG. 15D, and FIG. 15E illustrate one or more stages of an example of a method for manufacturing an electronic device according to some arrangements of the present disclosure.

FIG. 16A, FIG. 16B, and FIG. 16C illustrate one or more stages of an example of a method for manufacturing an electronic device according to some arrangements of the present disclosure.

FIG. 17A, FIG. 17B, FIG. 17C, FIG. 17D, FIG. 17E, FIG. 17F, and FIG. 17G illustrate one or more stages of an example of a method for manufacturing an electronic device according to some arrangements of the present disclosure.

FIG. 18A, FIG. 18B, and FIG. 18C illustrate one or more stages of an example of a method for manufacturing an electronic device according to some arrangements of the present disclosure.

FIG. 19 is a cross-sectional view of an electronic device, in accordance with an arrangement of the present disclosure.

FIG. 20 is a cross-sectional view of an electronic device, in accordance with an arrangement of the present disclosure.

FIG. 21 is a cross-sectional view of an electronic device, in accordance with an arrangement of the present disclosure.

FIG. 22 is a cross-sectional view of an electronic device, in accordance with an arrangement of the present disclosure.

FIG. 23 is a cross-sectional view of an electronic device, in accordance with an arrangement of the present disclosure.

FIG. 24 is a cross-sectional view of an electronic device, in accordance with an arrangement of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

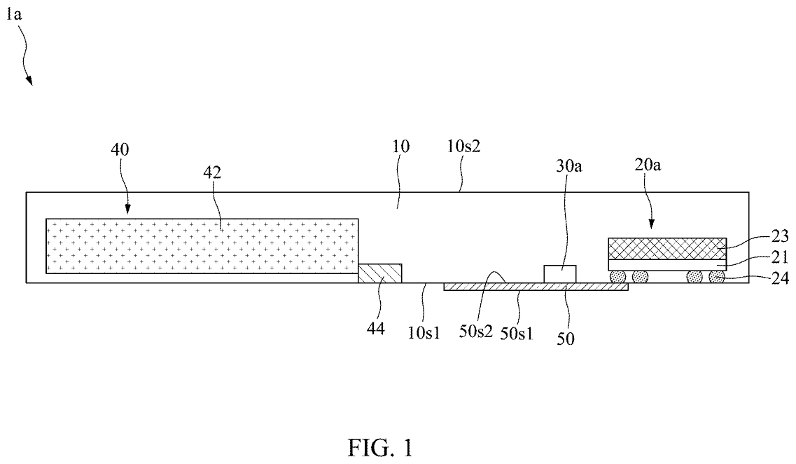

FIG. 1 is a cross-sectional view of an electronic device 1a, in accordance with an arrangement of the present disclosure. In some arrangements, the electronic device 1a may be applicable to, for example, a wireless device, such as user equipment (UE), a mobile station, a mobile device, an apparatus communicating with the Internet of Things (IoT), etc. In some arrangements, the electronic device 1a may be or include a portable device. In some arrangements, the electronic device 1a may support fifth generation (5G) communications, such as sub-6 GHz frequency bands and/or millimeter (mm) wave frequency bands. For example, the electronic device 1a may incorporate both sub-6 GHz devices and mm wave devices. In some arrangements, the electronic device 1a may support beyond-5G or 6G communications, such as terahertz (THz) frequency. The electronic device 1a may be configured to radiate and/or receive electromagnetic signals, such as radio frequency (RF) signals. For example, the electronic device 1a may be configured to operate in a frequency between about 10 GHz and about 10 THz, such as 10 GHz, 20 GHz, 30 GHz, 40 GHz, 50 GHz, 100 GHz, 300 GHz, 1 THz, 5 THz, or 10 THz. In some arrangements, the electronic device 1a may include a flexible encapsulant 10, an electronic package 20a, an electronic component 30a, an energy storage component 40, and a conductive connection 50.

The flexible encapsulant 10 (or bendable, pliable, adjustable, and/or stretchable encapsulant) may include insulation or dielectric material. In some arrangements, the flexible encapsulant 10 may be bendable, pliable, adjustable, and/or stretchable. The flexible encapsulant 10 may include silicon rubber, thermoplastic material (e.g., thermoplastic polyurethane (TPU)), polyethers, polyesters, co-polymers of polyether urethanes, polyester urethanes, polysulfones, polybutadiene-styrene, elastomers, hydrogels formed from copolymers of polyethylene glycol and polylactide, polyglycolide or copolymers of polylactide-co-glycolide polyacrylate rubber, ethylene-acrylate rubber, polyester urethane, bromo isobutylene isoprene, polybutadiene, chloro isobutylene isoprene, polychloroprene, chlorosulphonated polyethylene, epichlorohydrin, ethylene propylene, ethylene propylene diene monomer, polyether urethane, perfluorocarbon rubber, fluorinated hydrocarbon, fluorosilicone, fluorocarbon rubber, hydrogenated nitrile butadiene, polyisoprene, isobutylene isoprene butyl, acrylonitrile butadiene, polyurethane, styrene butadiene, styrene ethylene butylene styrene copolymer, polysiloxane, vinyl methyl silicone, acrylonitrile butadiene carboxy monomer, styrene butadiene carboxy monomer, thermoplastic polyether-ester, styrene butadiene block copolymer, styrene butadiene carboxy block copolymer, synthetic polyisoprene, polybutadiene, chloroprene rubber, polychloroprene, neoprene, baypren, butyl rubber, halogenated butyl rubbers, styrene-butadiene Rubber, nitrile rubber, hydrogenated nitrile rubber, ethylene propylene rubber, ethylene propylene diene rubber, epichlorohydrin rubber polyacrylic rubber, silicone rubber, fluorosilicone rubber, fluorosilicone rubber, fluroelastomers viton, tecnoflon, fluorel, aflas and dai-el, perfluoroelastomers tecnoflon PFR, kalrez, chemraz, perlast, polyether block amides, chlorosulfonated polyethylene, hypalon, ethylene-vinyl acetate, and combinations thereof. In some arrangements, the flexible encapsulant 10 may be formed by a molding technique, such as compression molding, injection molding, or transfer molding. In some arrangements, the flexible encapsulant 10 may be formed by a lamination technique, and the flexible encapsulant 10 may include multiple laminated films. The flexible encapsulant 10 may have a surface 10s1 (or a bottom surface) and a surface 10s2 (or a top surface) opposite to the surface 10s1.

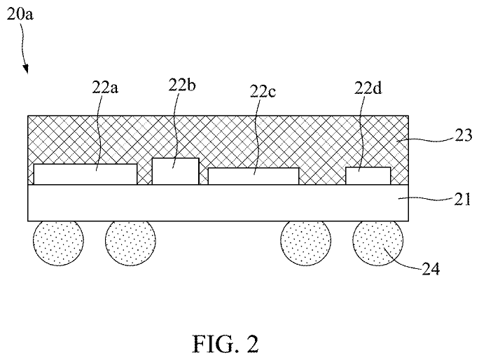

The electronic package 20a may be embedded within the flexible encapsulant 10. The electronic package 20a may abut the surface 10s1 of the flexible encapsulant 10. Please refer to FIG. 2, which illustrates the electronic package 20a in detail. In some arrangements, the electronic package 20a may include a system in package (SiP) device, which integrates multiple dies and can perform and/or process multiple functions. The electronic package 20a may include a carrier 21, electronic components 22a, 22b, 22c, and 22d, a package body 23, and terminals 24.

The carrier 21 may include, for example, a printed circuit board (PCB), such as a paper-based copper foil laminate, a composite copper foil laminate, or a polymer-impregnated glass-fiber-based copper foil laminate.

The electronic components 22a to 22d may be disposed over the carrier 21. Each of the electronic components 22a to 22d may include a semiconductor substrate, one or more integrated circuit (IC) devices and one or more overlying interconnection structures therein. The IC devices may include active devices and/or passive devices. For example, the active device may include a logic die (e.g., application processor (AP), system-on-a-chip (SoC), central processing unit (CPU), graphics processing unit (GPU), microcontroller unit (MCU), etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active devices (e.g., charger IC device, Bluetooth devices, and the like). The passive device may include a resistor, capacitor, inductor, or a combination thereof. In some arrangements, the electronic components 22a to 22d may have different dimensions (e.g., height, surface area, and the like) and may be electrically connected to the carrier 21 by a flip-chip technique, a wire-bonding technique, or other suitable techniques.

The package body 23 may be disposed over the carrier 21. The package body 23 may encapsulate the electronic components 22a to 22d. In some arrangements, the package body 23 may be made of molding material that may include, for example, a Novolac-based resin, an epoxy-based resin, a silicone-based resin, or other suitable encapsulant. Suitable fillers may also be included, such as powdered SiO₂.

The terminal 24 may be disposed under the carrier 21. The terminal 24 may include a solder ball, such as a controlled collapse chip connection (C4) bump, a ball grid array (BGA), a land grid array (LGA), and so on. In some arrangements, the terminal 24 may include a solder material(s), which may include alloys of gold and tin solder or alloys of silver and tin solder, or other suitable materials. With reference to FIG. 1, the terminal 24 may be exposed by the surface 10s1 of the flexible encapsulant 10 in some arrangements. The terminal 24 may be encapsulated by the flexible encapsulant 10.

The electronic component 30a may be embedded within the flexible encapsulant 10. The electronic component 30a may abut the surface 10s1 of the flexible encapsulant 10. In some arrangements, the electronic component 30a may include active devices and/or passive devices. In some arrangements, the electronic component 30a may include an antenna. For example, the electronic component 30a may include, for example but without being limited to, a directional antenna, an omnidirectional antenna, an antenna array, a dipole antenna and/or a patch antenna. The electronic component 30a may be configured to radiate and/or receive electromagnetic signals, such as radio frequency (RF) signals. For example, the electronic component 30a may include an antenna in package (AiP), an antenna on package (AoP), and the like.

The energy storage component (or power storage component) 40 may be embedded within the flexible encapsulant 10. The energy storage component 40 may be configured to provide the electronic package 20a or other devices with power. The energy storage component 40 may include a battery pack 42 and electrodes 44. The battery pack 42 may include a battery cell (e.g., a primary cell which is not rechargeable, a secondary cell which is rechargeable, or a fuel cell), an exterior member (e.g., a laminate film in which a fusion layer, a metal layer, and a surface protective layer are stacked in this order), a switch unit (e.g., a charge control switch and a discharge control switch), a current detection resistor, a temperature detection element (e.g., a thermistor), and a control unit configured to control the switch unit. The energy storage component 40 may include a flexible battery cell or other components.

The electrodes 44 may include a positive electrode and a negative electrode, which are electrically connected to other devices. In some arrangements, the electrode 44 may be exposed by the surface 10s1 of the flexible encapsulant 10.

In some arrangements, the conductive connection 50 (or conductive trace) may be disposed on or under the surface 10s1 of the flexible encapsulant 10. The conductive connection 50 may be configured to electrically connect the electronic package 20a, the electronic component 30a, the energy storage component 40, and/or other devices. In some arrangements, the conductive connection 50 may include a conductive paste (e.g., silver paste, copper paste, gold paste, or other suitable pastes), a conductive ink which may include gold, silver, copper, or other suitable materials mixed with resin or other polymer materials, or other suitable conductive materials. The conductive connection 50 may include a surface 50s1 (or a bottom surface) and a surface 50s2 (or a top surface) opposite to the surface 50s1. In some arrangements, the surface 50s1 may be spaced apart from the flexible encapsulant 10.

In a comparative example, a flexible device includes a flexible carrier (e.g., polyimide with coefficient of thermal expansion (CTE) of 20˜60 ppm/° C.) and an encapsulant (e.g., silicon rubber with CTE of 150˜200 ppm/° C.) formed over the flexible carrier. A conductive connection is formed over the flexible carrier and encapsulated by the encapsulant. Due to the mismatch in CTE between the flexible carrier and the encapsulant, delamination may occur. To address this issue, in the present arrangement, the flexible carrier is eliminated, and the conductive connection is directly formed on the surface (either the bottom or top surface) of the encapsulant. As a result, the problem of delamination can be prevented in the arrangements described in this disclosure.

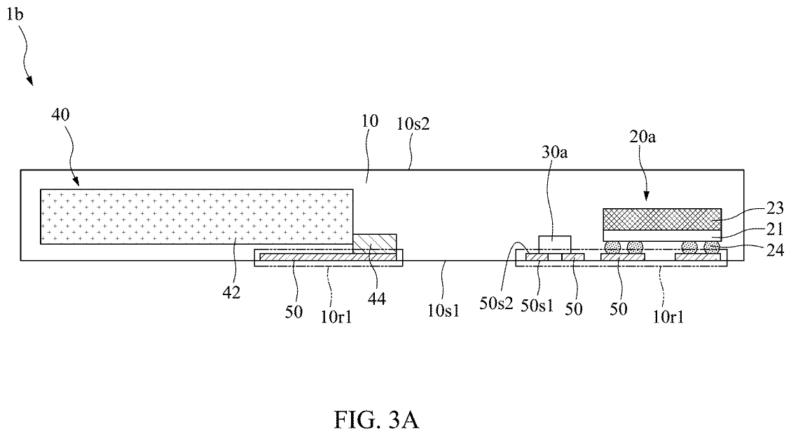

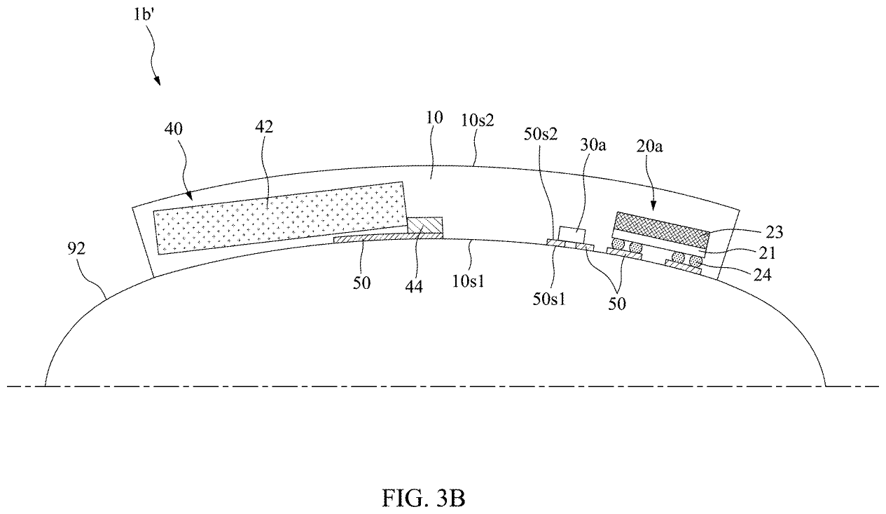

FIG. 3A is a cross-sectional view of an electronic device 1b, in accordance with an arrangement of the present disclosure. The electronic device 1b is similar to the electronic device 1a as shown in FIG. 1, with the following differences.

In some arrangements, the flexible encapsulant 10 may define an encapsulant-defined pattern 10r1 (or a predetermined pattern which is configured to accommodate traces or circuits) abutting the surface 10s1. The encapsulant-defined pattern 10r1 may be an opening of the flexible encapsulant 10 recessed from the surface 10s1, which is configured to accommodate the conductive connection 50. In some arrangements, the electrode 44 of the energy storage component 40 may be exposed by the encapsulant-defined pattern 10r1. In some arrangements, the terminal 24 of the electronic package 20a may be exposed by the encapsulant-defined pattern 10r1. In some arrangements, the terminal (not shown) of the electronic component 30a may be exposed by the encapsulant-defined pattern 10r1. In some arrangements, the conductive connection 50 may be disposed within the encapsulant-defined pattern 10r1 to electrically connect the electronic package 20a, the electronic component 30a, the energy storage component 40, and/or other suitable devices. In some arrangements, the encapsulant-defined pattern 10r1 can be formed or defined initially, followed by the formation of a conductive material within it to define the conductive connection 50. The pattern of the encapsulant-defined pattern 10r1 can be predetermined, and then a conductive material can be filled within it, allowing the conductive connection 50 to inherit the pattern of the encapsulant-defined pattern 10r1. In some arrangements, the surface 50s1 of the conductive connection 50 may be substantially aligned with or coplanar with the surface 10s1 of the flexible encapsulant 10. In some arrangements, a slight difference in height may occur between the surface 10s1 of the flexible encapsulant 10 and the surface 50s1 of the conductive connection 50 due to error during processes. Unlike a comparative example, the pattern of a conductive connection is defined initially, and then an encapsulant is formed to cover the conductive connection.

FIG. 3B is a cross-sectional view of an electronic device 1b′, in accordance with an arrangement of the present disclosure. In some arrangements, the flexible encapsulant 10 may be stretched and/or bent to be conformally disposed on an object 92 which defines a curved surface abutting the electronic device 1b′.

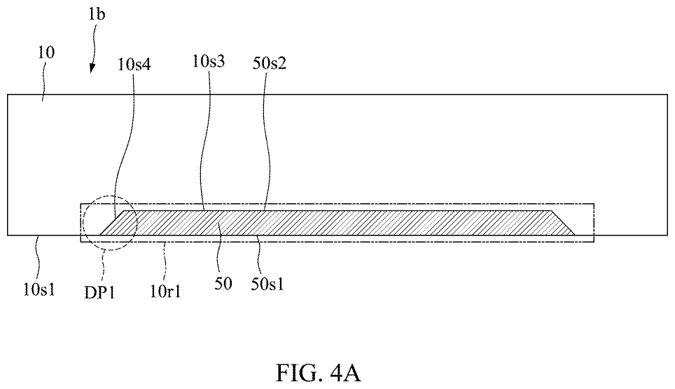

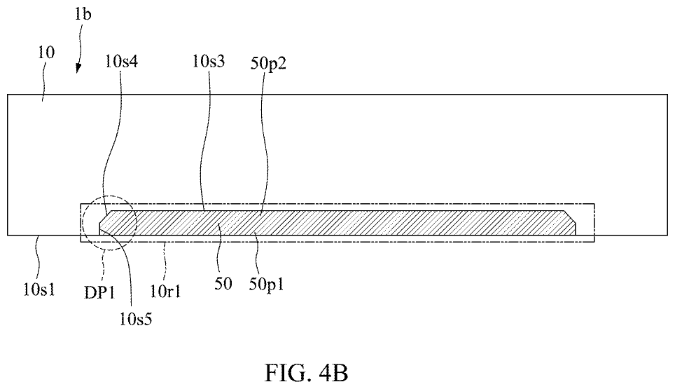

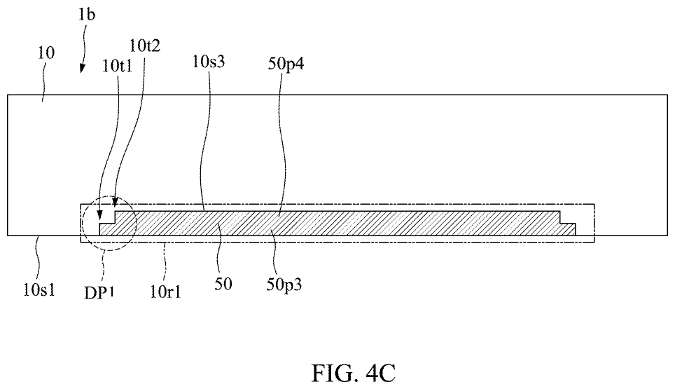

FIG. 4A is a partial enlarged view of an electronic device 1b, in accordance with an arrangement of the present disclosure. In some arrangements, the encapsulant-defined pattern 10r1 may have a demoulding pattern DP1. In some arrangements, a temporary carrier with a predetermined pattern is provided, and the flexible encapsulant 10 is formed over the temporary carrier to inherit the pattern of the temporary carrier, which will be described in detail later. Once the flexible encapsulant 10 is formed, the temporary carrier is removed. To make the removal process easier, the predetermined pattern of the temporary carrier can be designed with a demoulding structure, which will also be inherited by the encapsulant-defined pattern 10r1 of the flexible encapsulant 10. Further, the conductive connection 50 will be filled within the encapsulant-defined pattern 10r1 and may conform to the demoulding pattern DP1. In some arrangements, the demoulding pattern DP1 may include a draft angle or profiles facilitating the separation of the flexible encapsulant 10 from the temporary carrier.

In some arrangements, the demoulding pattern DP1 may include a tapered profile. For example, the demoulding pattern DP1 may be tapered toward the surface 10s2 (shown in FIG. 3A) of the flexible encapsulant 10. The flexible encapsulant 10 may have a surface 10s3 and a surface 10s4. The surface 10s3 may serve as a bottom (or a top) of the encapsulant-defined pattern 10r1. The surface 10s3 may be substantially parallel to the surface 10s1 and at a level (or elevation) different from that of the surface 10s1. The surface 10s4 may extend between the surface 10s1 and surface 10s3. In some arrangements, an obtuse angle may be exhibited between the surface 10s3 and surface 10s4. In some arrangements, the surface 10s4 may be slanted with respect to the surface 10s1. In some arrangements, the surface 10s4 may be slanted with respect to the surface 10s3. In some arrangements, the conductive connection 50 may be tapered toward the surface 10s2 (shown in FIG. 3) of the flexible encapsulant 10. In some arrangements, the conductive connection 50 may include a slanted lateral surface (not annotated) extending between the surface 50s1 and surface 50s2.

FIG. 4B is a partial enlarged view of an electronic device 1b, in accordance with an arrangement of the present disclosure. In some arrangements, the demoulding pattern DP1 may have a uniform portion (or a substantially uniform portion) with a uniform dimension (e.g., width or length) in a cross-sectional view and a tapered portion over the uniform dimension. The uniform portion may abut the surface 10s1, and the tapered portion may be spaced apart from the surface 10s1 by the uniform portion. In some arrangements, the flexible encapsulant 10 may have a surface 10s5. The surface 10s5 may extend between the surface 10s1 and surface 10s4. In some arrangements, the surface 10s5 may be substantially perpendicular to the surface 10s1. In some arrangements, the surface 10s4 may be slanted with respect to the surface 10s5. In some arrangements, an obtuse angle may be exhibited between the surface 10s4 and surface 10s5. In some arrangements, the conductive connection 50 may have a uniform portion (or a substantially uniform portion) 50p1 with a uniform dimension (e.g., width or length) in a cross-sectional view and a tapered portion 50p2 over the uniform portion 50p1.

FIG. 4C is a partial enlarged view of an electronic device 1b, in accordance with an arrangement of the present disclosure. In some arrangements, the demoulding pattern DP1 may include step profiles 10t1 and 10t2, each of which may be composed of a vertical surface extending between two horizontal surfaces. The step profile 10t1 may abut the surface 10s1. The step profile 1012 may be spaced part from the surface 10s1 by the step profile 10t1. In some arrangements, the step profile 10t1 may define a lower portion with a greater dimension (e.g., width, length, or surface), and the step profile 10t2 may define an upper portion with a lesser dimension (e.g., width, length, or surface). In some arrangements, the conductive connection 50 may include step profiles. In some arrangements, the conductive connection 50 may include a lower portion 50p3 with a greater dimension (e.g., width, length, or surface) and an upper portion 50p4 with a lesser dimension (e.g., width, length, or surface).

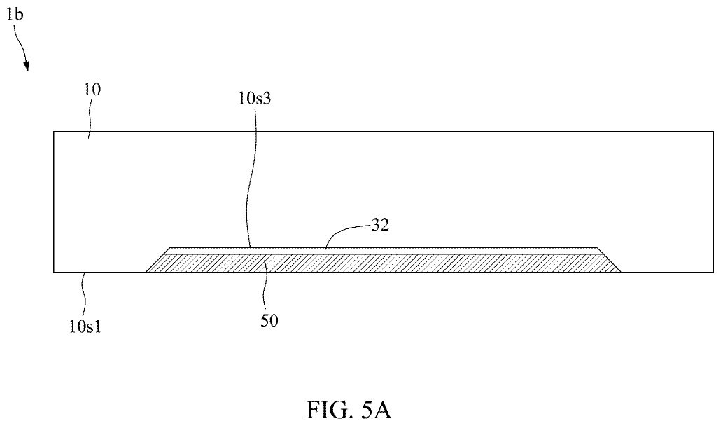

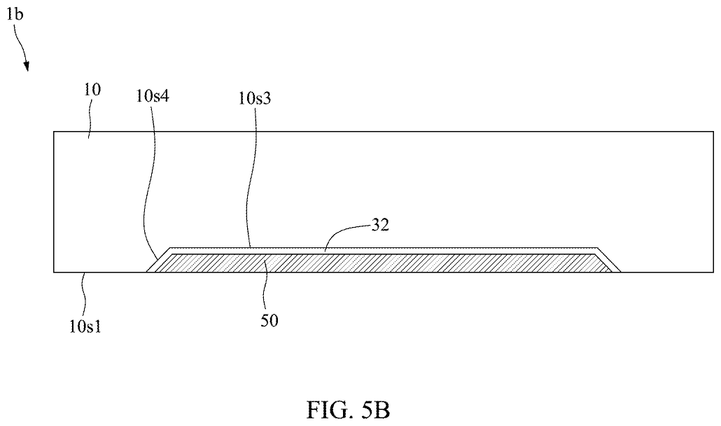

FIG. 5A is a partial enlarged view of an electronic device 1b, in accordance with other arrangements of the present disclosure.

In some arrangements, the electronic device 1b may further include an adhesive layer 32. The adhesive layer 32 may be configured to attach the conductive connection 50 to the flexible encapsulant 10. The adhesive layer 32 may prevent the delamination between the conductive connection 50 and the flexible encapsulant 10. In some arrangements, the adhesive layer 32 may include octamethyltrisilozane, tetrakis(2-butoxyethyl) orthosilicate, tetra n-butyl titanate, or other suitable materials.

FIG. 5B is a partial enlarged view of the electronic device 1b as shown in FIG. 3A, in accordance with an arrangement of the present disclosure. In some arrangements, the adhesive layer 32 may further be disposed on the surface 10s4 of the flexible encapsulant 10.

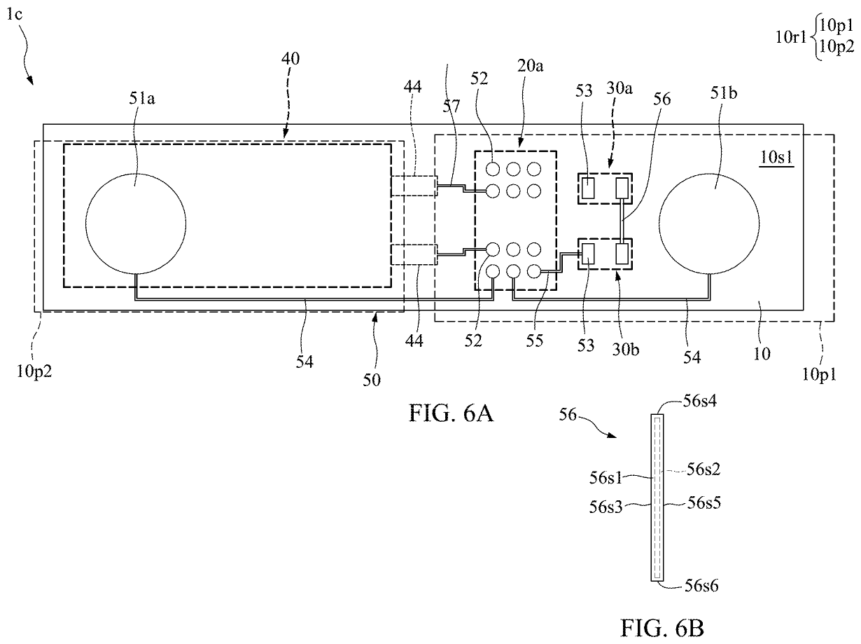

FIG. 6A is a bottom view of a layout of an electronic device 1c, in accordance with an arrangement of the present disclosure.

In some arrangements, the conductive connection 50 may include conductive elements 51a, 51b, 52, 53, 54, 55, 56, and 57 (or conductive connections). Each of the conductive elements 51a to 57 may be an electrode, a pad, or a trace. Each of the conductive elements 51a to 57 may be within the encapsulant-defined pattern 10r1 of the flexible encapsulant 10. The conductive element 51a and conductive element 51b may be connected to an external object (e.g., a living creature or an electronic device). For example, the conductive element 51a and conductive element 51b may be configured to be attached to the skin of an object to obtain a bio-signal. The bio-signal may be processed by, for example, the electronic package 20a, and be transmitted to the the user's mobile phone or medical institutions for monitoring and recording the body condition through the electronic component 30a. In this arrangement, the electronic device 1c may function as an electronic patch. When the electronic device 1c is attached to an object, it can be stretchable and bendable to accommodate the object's motion. As a result, the flexible encapsulant 10 is relatively bendable, pliable, adjustable, and/or stretchable.

The conductive element 52 may be electrically connected to the terminal (e.g., the terminal 24 as shown in FIG. 3A) of the electronic package 20a. The conductive element 53 may be electrically connected to the terminal of the electronic component 30a or electronic component 30b. The conductive element 54 may be configured to electrically connect the conductive connection 50a (or conductive connection 50b) and the electronic package 20a. The conductive element 55 may be configured to electrically connect the electronic package 20a and the electronic component 30a (or electronic component 30b). The conductive element 56 may be configured to electrically connect the electronic component 30a and electronic component 30b. The conductive element 57 may be configured to electrically connect the electronic package 20a and the electrode 44 of the energy storage component 40.

In some arrangements, the encapsulant-defined pattern 10r1 may include a circuit region 10p1 and a circuit region 10p2. The density (e.g., the (average) area recessed from the surface 10s1 of the flexible encapsulant 10 per unit area) of the circuit region 10p1 may be greater than that of the circuit region 10p2. The conductive connection 50 may be distributed in the circuit region 10p1 and circuit region 10p2. For example, the conductive element 51b, conductive element 52, conductive element 53 may be disposed in the circuit region 10p2. The conductive element 51a may be disposed in the circuit region 10p1. In some arrangements, the circuit density of the conductive connection 50 within the circuit region 10p1 may be greater than that of the circuit region 10p2. In some arrangements, the depth (e.g., a distance between the surface 10s1 and surface 10s3 as shown in FIG. 4A) of the encapsulant-defined pattern 10r may be nonuniform. For example, the depth of the circuit region 10p1 may be different from that of the circuit region 10p2. In some arrangements, the thickness (e.g., a distance between the surface 10s1 and surface 10s3 as shown in FIG. 4A) of the conductive connection 50 may be nonuniform. For example, the conductive elements 51a to 57 may have different thicknesses in some arrangements.

FIG. 6B illustrates a bottom view of the conductive element 56. The conductive element 56 may have a surface 56s1 (or a bottom surface) exposed by the surface 10s1 and a surface 56s2 (or a top surface) opposite to the surface 56s1. The conductive element 56 may have surfaces 56s3, 56s4, 56s5, and 56s6 (or lateral surfaces), each of which extending between the surfaces 56s1 and 56s2. In some arrangements, each of the surfaces 56s3, 56s4, 56s5, and 56s6 is slanted with respect to the surface 56s1. The conductive element 56 may be tapered along a direction from the surface 56s1 toward the surface 56s2. Therefore, the conductive element 56 may have a greater dimension (e.g., length or width) abutting the surface 56s1 and a less dimension (e.g., length or width) abutting the surface 56s2 along a first direction (e.g., a direction extending between the surfaces 56s3 and 56s5) and a second direction (e.g., a direction extending between the surfaces 56s2 and 56s6).

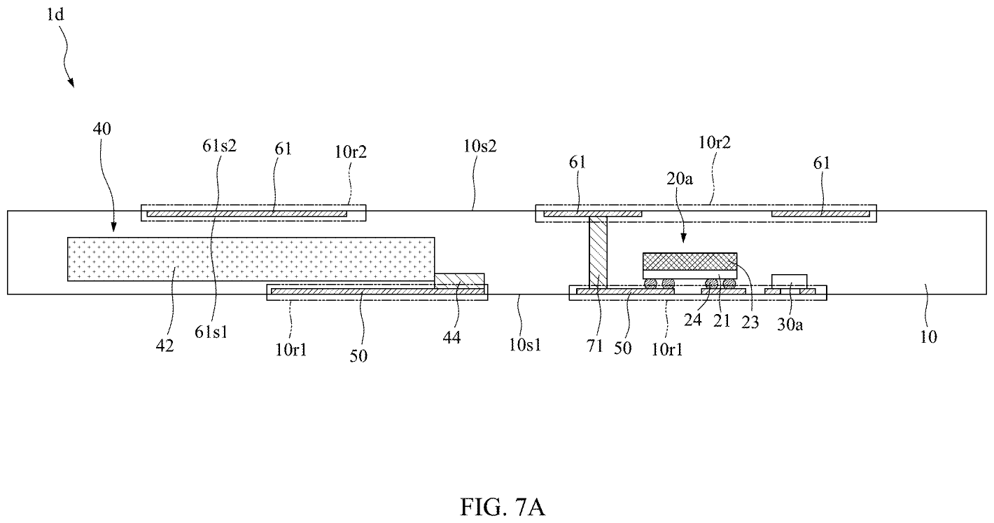

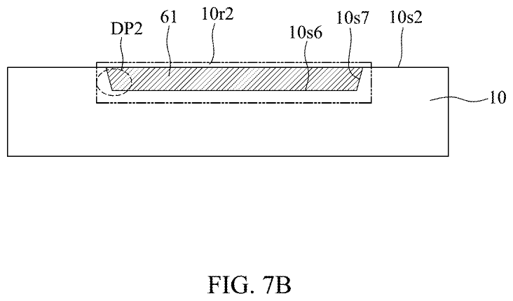

FIG. 7A is a cross-sectional view of an electronic device 1d, in accordance with an arrangement of the present disclosure. The electronic device 1d is similar to the electronic device 1a as shown in FIG. 1A, with the following differences. In some arrangements, the electronic device 1d may further include a conductive connection 61 and a conductive pillar 71.

In some arrangements, the conductive connection 61 may abut the surface 10s2 of the flexible encapsulant 10. In some arrangements, the conductive connection 61 may be embedded within the flexible encapsulant 10. In some arrangements, the conductive connection 61 may include a conductive paste (e.g., silver paste, copper paste, gold paste, or other suitable pastes), a conductive ink which may include gold, silver, copper, or other suitable materials mixed with resin or other polymer materials, or other suitable conductive materials. The conductive connection 61 may include a surface 61s1 (or a bottom surface) and a surface 61s2 (or a top surface) opposite to the surface 61s1. In some arrangements, the surface 61s2 of the conductive connection 61 may be substantially aligned with or coplanar with the surface 10s2 of the flexible encapsulant 10. In some arrangements, a slight difference in height may occur between the surface 10s2 of the flexible encapsulant 10 and the surface 61s1 of the conductive connection 61 due to error during processes.

In some arrangements, the conductive pillar 71 may extend between the conductive connection 50 and the conductive connection 61. In some arrangements, the conductive pillar 71 may be embedded within the flexible encapsulant 10. The conductive pillar 71 may be electrically connected to the conductive connection 50. The conductive pillar 71 may be electrically connected to the conductive connection 61. The conductive pillar 71 may include or be replaced by a through conductive via, conductive element, or a conductive pin. The conductive pillar 71 may include or be made of copper (Cu), tin (Sn), silver (Ag), titanium (Ti), nickel (Ni), or a combination of two or more thereof.

In some arrangements, the flexible encapsulant 10 may include an encapsulant-defined pattern 10r2. In some arrangements, the encapsulant-defined pattern 10r2 may abut the surface 10s2. The encapsulant-defined pattern 10r2 may be an opening of the flexible encapsulant 10 recessed from the surface 10s2, which is configured to accommodate the conductive connection 61. In some arrangements, the encapsulant-defined pattern 10r2 can be formed initially, followed by the formation of a conductive material within it to define the conductive connection 61. The pattern of the encapsulant-defined pattern 10r2 can be predetermined, and then a conductive material can be filled within it, allowing the conductive connection 61 to inherit the pattern of the encapsulant-defined pattern 10r2. Unlike a comparative example, the pattern of a conductive connection is defined initially, and then an encapsulant is formed to cover the conductive connection.

FIG. 7B is a partial enlarged view of the electronic device 1d as shown in FIG. 7A, in accordance with an arrangement of the present disclosure.

In some arrangements, the encapsulant-defined pattern 10r2 may have a demoulding pattern DP2. In some arrangements, a mold chase with a predetermined pattern is provided, and the flexible encapsulant 10 can inherit the pattern of the mold chase. Once the flexible encapsulant 10 is formed, the mold chase is removed. To make the removal process easier, the predetermined pattern of the mold chase can be designed with a demoulding structure, which will also be inherited by the encapsulant-defined pattern 10r2 of the flexible encapsulant 10. Further, the conductive connection 61 will be filled within the encapsulant-defined pattern 10r2 and may conform to the demoulding pattern DP2. In some arrangements, the demoulding pattern may include a draft angle or profiles facilitating the separation of the flexible encapsulant 10 from the temporary carrier.

In some arrangements, the demoulding pattern DP2 may include a tapered profile. For example, the demoulding pattern DP2 may be tapered toward the surface 10s1 (shown in FIG. 7A) of the flexible encapsulant 10. The flexible encapsulant 10 may have a surface 10s6 and a surface 10s7. The surface 10s6 may serve as a bottom (or a top) of the encapsulant-defined pattern 10r2. The surface 10s6 may be substantially parallel to the surface 10s2 and at a level (or elevation) different from that of the surface 10s2. The surface 10s7 may extend between the surface 10s2 and surface 10s6. In some arrangements, an obtuse angle may be exhibited between the surface 10s6 and surface 10s7. In some arrangements, the surface 10s7 may be slanted with respect to the surface 10s2. In some arrangements, the surface 10s7 may be slanted with respect to the surface 10s6. In some arrangements, the conductive connection 61 may be tapered toward the surface 10s1 (shown in FIG. 7A) of the flexible encapsulant 10.

Although not shown, the demoulding pattern DP2 may have other profiles, such as the pattern as shown in FIG. 4B or FIG. 4C. In some arrangements, the demoulding pattern DP2 may have a nonuniform portion abutting the surface 10s2 and a uniform portion spaced apart from the surface 10s2. In some arrangements, the demoulding pattern DP2 may have step profiles with different dimensions. The conductive connection 50 may conform to the demoulding pattern DP2 of the encapsulant-defined pattern 10r2. Further, an adhesive layer, which has a material similar to or the same as that of the adhesive layer 32, may be disposed between the conductive connection 61 and the flexible encapsulant 10.

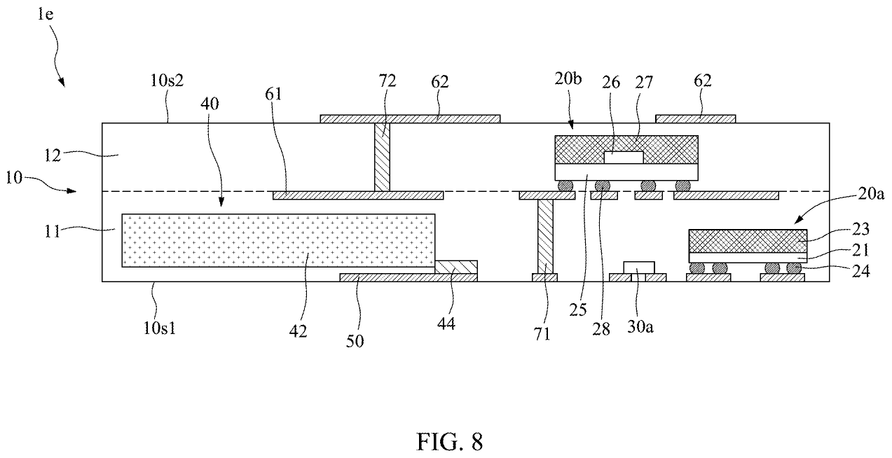

FIG. 8 is a cross-sectional view of an electronic device 1e, in accordance with an arrangement of the present disclosure. The electronic device 1e is similar to the electronic device 1a as shown in FIG. 1A, with the following differences.

In some arrangements, the flexible encapsulant 10 may include an insulation layer 11 and an insulation layer 12. Each of the insulation layer 11 and insulation layer 12 may be bendable and/or stretchable. In some arrangements, the material of the insulation layer 11 and insulation layer 12 may be the same as or similar to that of the flexible encapsulant 10. The bottom surface of the insulation layer 11 may function as the surface 10s1 of the flexible encapsulant 10. The top surface of the insulation layer 12 may function as the surface 10s2 of the flexible encapsulant 10. In some arrangements, a nonobvious boundary may be between the insulation layer 11 and insulation layer 12. In some arrangements, no boundary is between the insulation layer 11 and insulation layer 12. The electronic package 20a, the electronic component 30a, and energy storage component 40 may be disposed within the insulation layer 11. The conductive connection 61 may be disposed within the insulation layer 11 and abut the insulation layer 12. The conductive pillar 71 may be disposed within the insulation layer 11. The insulation layer 12 may be disposed over the top surface of the insulation layer 11.

The electronic device 1e may further include an electronic package 20b, a conductive connection 62, and a conductive pillar 72. The electronic package 20b. The electronic package 20b may be embedded within the insulation layer 12. The electronic package 20b may abut the surface 10s2 of the flexible encapsulant 10. In some arrangements, the electronic package 20b may include a system in package (SiP) device, which integrates multiple dies and can perform and/or process multiple functions. The electronic package 20b may include a carrier 25, an electronic component(s) 26, a package body 27, and terminals 28.

The carrier 25 may include, for example, a printed circuit board, such as a paper-based copper foil laminate, a composite copper foil laminate, or a polymer-impregnated glass-fiber-based copper foil laminate.

The electronic component 26 may be disposed over the carrier 25. The electronic component 26 may include a semiconductor substrate, one or more IC devices and one or more overlying interconnection structures therein. The IC devices may include active devices and/or passive devices. The electronic component 26 may include a logic die (e.g., AP die, SoC die, CPU die, GPU die, MCU die, etc.), a memory die (e.g., DRAM die, SRAM die, etc.), a power management die (e.g., PMIC die), an RF die, a sensor die, a MEMS die, a signal processing die (e.g., DSP die), a front-end die (e.g., AFE die) or other active devices (e.g., charger IC device, Bluetooth devices, and the like). The passive device may include a resistor, capacitor, inductor, or a combination thereof. In some arrangements, the electronic component 26 may be electrically connected to the carrier 25 by a flip-chip technique, a wire-bonding technique, or other suitable techniques.

The package body 27 may be disposed over the carrier 25. The package body 27 may encapsulate the electronic component 26. The package body 27 may be embedded within the insulation layer 12. In some arrangements, the package body 27 may be made of molding material that may include, for example, a Novolac-based resin, an epoxy-based resin, a silicone-based resin, or other suitable encapsulant. Suitable fillers may also be included, such as powdered SiO₂.

The terminal 28 may be disposed under the carrier 25. The terminal 28 may include a solder ball, such as a controlled collapse chip connection bump, a ball grid array, a land grid array, and so on. In some arrangements, the terminal 28 may include a solder material(s), which may include alloys of gold and tin solder or alloys of silver and tin solder, or other suitable materials.

The conductive connection 62 may be disposed on or over the surface 10s2 of the flexible encapsulant 10. The conductive connection 62 may be disposed over the insulation layer 12. In some arrangements, the conductive connection 62 may include a conductive paste (e.g., silver paste, copper paste, gold paste, or other suitable pastes), a conductive ink which may include gold, silver, copper, or other suitable materials mixed with resin or other polymer materials, or other suitable conductive materials.

In some arrangements, the conductive pillar 72 may be disposed within the insulation layer 12. In some arrangements, the conductive pillar 72 may extend between the conductive connection 61 and conductive connection 62. The conductive pillar 72 may be electrically connected to the conductive connection 61. The conductive pillar 72 may be electrically connected to the conductive connection 62. The conductive pillar 72 may include or be replaced by a through conductive via, conductive element, or a conductive pin. The conductive pillar 72 may include or be made of copper, tin, silver, titanium, nickel, or a combination of two or more thereof.

In some arrangements, a projection of the electronic package 20b onto the surface 10s1 may be closer to a projection of the electronic package 20a onto the surface 10s1 than to a projection of the energy storage component 40 onto the surface 10s1. In some arrangements, the electronic package 20b may vertically overlap the electronic package 20a. In some arrangements, the electronic packages 20a and 20b may be closer to a side than to an opposite side of the flexible encapsulant 10. The electronic packages 20a and 20b may be concentrated on one side or in a specific region, and the opposite side or other regions remain free of electronic packages. Since the electronic package 20a and electronic package 20b may be located at the same side with relative to the energy storage component 40, delamination and/or cracking may be prevented when the electronic device 1e is bended or stretched.

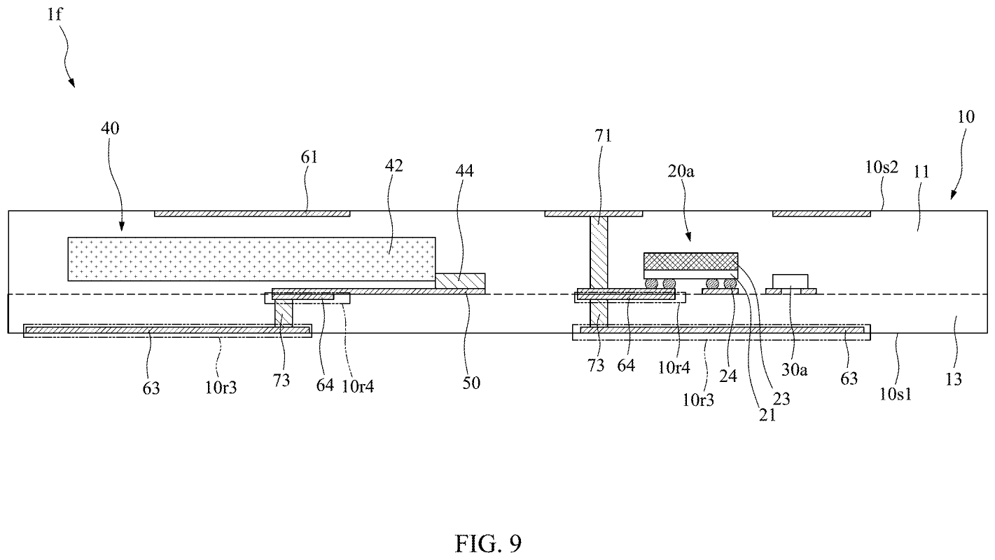

FIG. 9 is a cross-sectional view of an electronic device 1f, in accordance with an arrangement of the present disclosure. The electronic device 1f is similar to the electronic device 1b as shown in FIG. 3A, with the following differences.

In some arrangements, the electronic device 1f may further include an insulation layer 13, a conductive connection 63, a conductive connection 64, and a conductive pillar 73. In some arrangements, the material of the insulation layer 13 may be the same as or similar to that of the insulation layer 11. The bottom surface of the insulation layer 13 may function as the surface 10s1 of the flexible encapsulant 10. The top surface of the insulation layer 11 may function as the surface 10s2 of the flexible encapsulant 10 in this arrangement. In some arrangements, a nonobvious boundary may be between the insulation layer 11 and insulation layer 13. In some arrangements, no boundary is between the insulation layer 11 and insulation layer 13.

In some arrangements, the flexible encapsulant 10 may define an encapsulant-defined pattern 10r3 abutting the surface 10s1 or the bottom surface of the insulation layer 13. The encapsulant-defined pattern 10r1 may be an opening of the flexible encapsulant 10 recessed from the surface 10s1 or from the bottom surface of the insulation layer 13, which is configured to accommodate the conductive connection 63. In some arrangements. The encapsulant-defined pattern 10r3 can be formed initially, followed by the formation of a conductive material within it to define the conductive connection 63. The pattern of the encapsulant-defined pattern 10r3 can be predetermined, and then a conductive material can be filled within it, allowing the conductive connection 63 to inherit the pattern of the encapsulant-defined pattern 10r3. In some arrangements, the bottom surface (not annotated) of the conductive connection 63 may be substantially aligned with or coplanar with the surface 10s1 of the flexible encapsulant 10. The encapsulant-defined pattern 10r3 may include a demoulding pattern similar to the demoulding pattern DP1 as shown in FIG. 4A to FIG. 4C.

In some arrangements, the flexible encapsulant 10 may define an encapsulant-defined pattern 10r4 abutting the top surface of the insulation layer 13. The encapsulant-defined pattern 10r4 may be an opening of the flexible encapsulant 10 recessed from the top surface of the insulation layer 13, which is configured to accommodate the conductive connection 64. In some arrangements, the encapsulant-defined pattern 10r4 can be formed initially, followed by the formation of a conductive material within it to define the conductive connection 64. The pattern of the encapsulant-defined pattern 10r4 can be predetermined, and then a conductive material can be filled within it, allowing the conductive connection 64 to inherit the pattern of the encapsulant-defined pattern 10r4. The encapsulant-defined pattern 10r4 may include a demoulding pattern similar to the demoulding pattern DP1 as shown in FIG. 4A to FIG. 4C.

In some arrangements, the conductive connection 63 may abut the surface 10s1 of the flexible encapsulant 10. In some arrangements, the conductive connection 63 may include a conductive paste (e.g., silver paste, copper paste, gold paste, or other suitable pastes), a conductive ink which may include gold, silver, copper, or other suitable materials mixed with resin or other polymer materials, or other suitable conductive materials. The conductive connection 63 may inherit the demoulding profile of the encapsulant-defined pattern 10r3 of the flexible encapsulant 10. The function of the conductive connection 63 may be the same as or similar to that of the conductive element 51a.

In some arrangements, the conductive connection 64 may be disposed under the conductive connection 50. The conductive connection 64 may be electrically connected to the conductive connection 50. In some arrangements, the conductive connection 64 may include a conductive paste (e.g., silver paste, copper paste, gold paste, or other suitable pastes), a conductive ink which may include gold, silver, copper, or other suitable materials mixed with resin or other polymer materials, or other suitable conductive materials. The conductive connection 64 may inherit the demoulding profile of the encapsulant-defined pattern 10r4 of the flexible encapsulant 10.

In some arrangements, the conductive pillar 73 may be disposed within the insulation layer 13. In some arrangements, the conductive pillar 73 may extend between the conductive connection 63 and conductive connection 64. The conductive pillar 73 may be electrically connected to the conductive connection 63. The conductive pillar 73 may be electrically connected to the conductive connection 64. The conductive pillar 73 may include or be made of copper, tin, silver, titanium, nickel, or a combination of two or more thereof.

In this arrangement, the flexible encapsulant 10 may consist of multiple laminated layers, which allows for the creation of an electronic device that requires multiple conductive traces while still being flexible and stretchable.

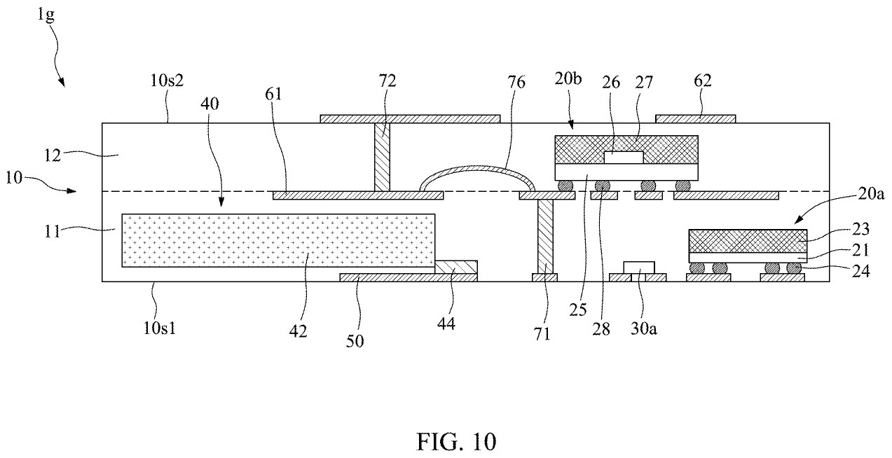

FIG. 10 is a cross-sectional view of an electronic device 1g, in accordance with an arrangement of the present disclosure. The electronic device 1g is similar to the electronic device 1e as shown in FIG. 8, with the following differences.

In some arrangements, the electronic device 1g may further include a conductive wire 76. In some arrangements, the conductive wire 76 may be disposed within the insulation layer 12. In some arrangements, the conductive wire 76 may be electrically connected to the conductive connection 61. The conductive wire 76 may be configured to electrically connect the electronic package 20b and the conductive connection 62. In some arrangements, a portion of the conductive connection 61 may be replaced with the conductive wire 76, which may reduce the dimensions (e.g., length) of the conductive connection 61. As a result, delamination between the conductive connection 61 and the insulation layer 12 may be reduced when the electronic device 1g is bent or stretched. The stretchability of the conductive wire 76 may be greater than that of the conductive connection, which may reduce the risk of electrical disconnection. Further, the conductive wire 76 may be electrically connected to the ground to shield the electronic package 20b from being interfered by electromagnetic interference (EMI). In some arrangements, multiple conductive wires 76 may surround the electronic package 20b to enhance EMI shielding.

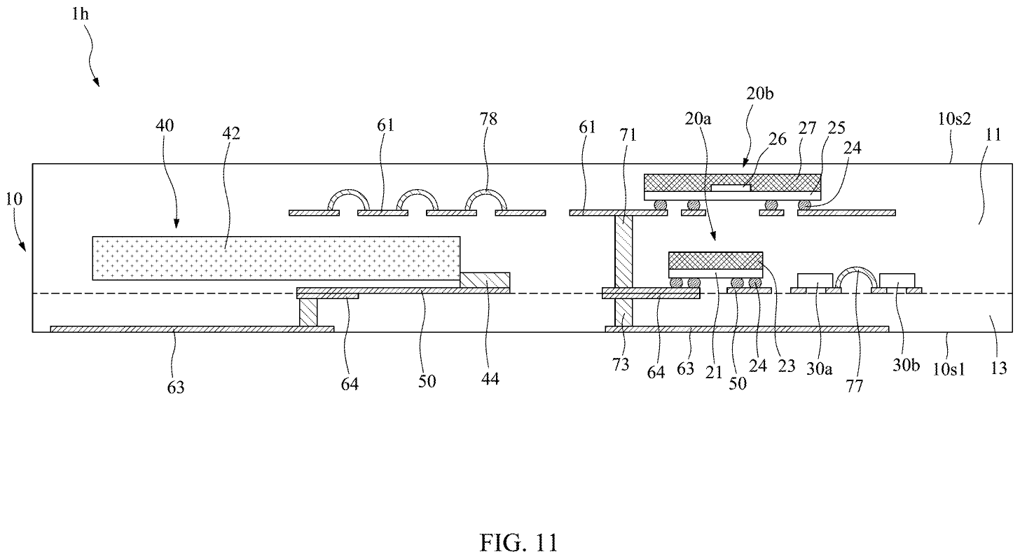

FIG. 11 is a cross-sectional view of an electronic device 1h, in accordance with an arrangement of the present disclosure. The electronic device 1h is similar to the electronic device 1f as shown in FIG. 9, with the following differences.

In some arrangements, the electronic device 1h may include conductive wires 77 and 78. The conductive wire 77 may be disposed within the flexible encapsulant 10. The conductive wire 77 may be electrically connected to the conductive connection 50. The conductive wire 77 may be electrically connected to the electronic component 30a and electronic component 30b. In some arrangements, a portion of the conductive connection 50 may be replaced with the conductive wire 77, which may reduce the dimensions (e.g., length) of the conductive connection 50. As a result, delamination between the conductive connection 50 and the flexible encapsulant 10 may be reduced when the electronic device 1h is bent or stretched.

The conductive wire 78 may be disposed within the flexible encapsulant 10. The conductive wire 77 may be located at a level (or height) different from that of the conductive wire 78 with respect to the surface 10s1 of the flexible encapsulant 10. The conductive wire 78 may be electrically connected to the conductive connection 61. In some arrangements, a portion of the conductive connection 61 may be replaced with the conductive wire 78, which may reduce the dimensions (e.g., length) of the conductive connection 61. As a result, delamination between the conductive connection 61 and the flexible encapsulant 10 may be reduced when the electronic device 1h is bent or stretched. In some arrangements, the conductive wire 78 may function as a passive component (e.g., an inductor), which is configured to control or adjust the impedance between the electronic components. In some arrangements, the conductive wire 78 may be configured to function as a regulator and/or a filter.

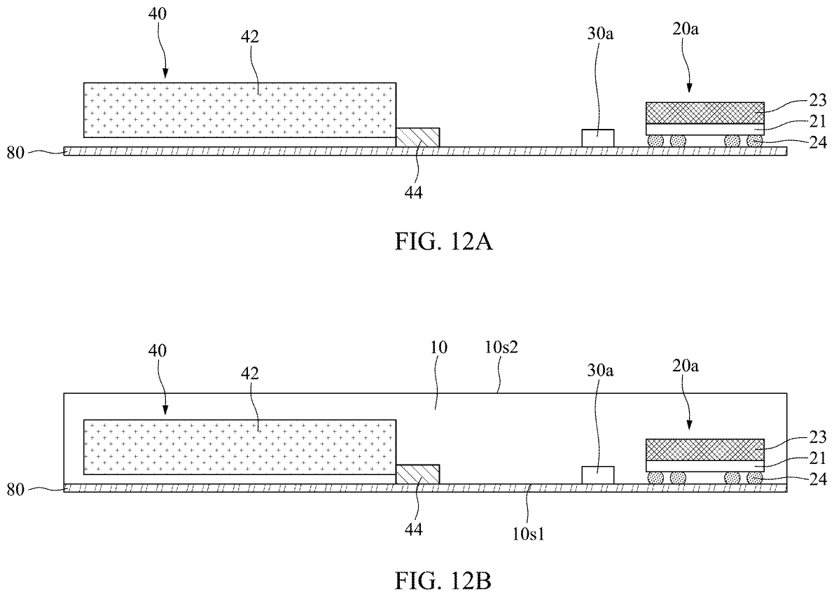

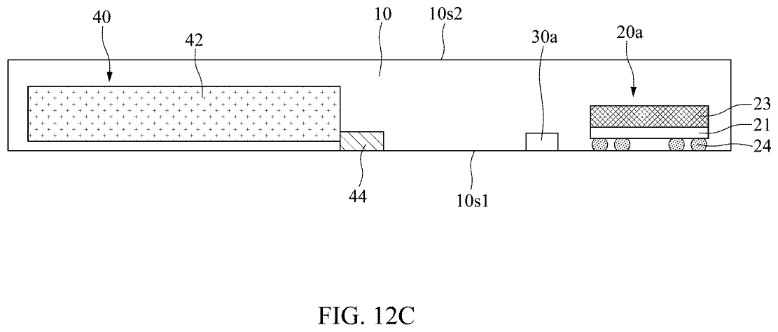

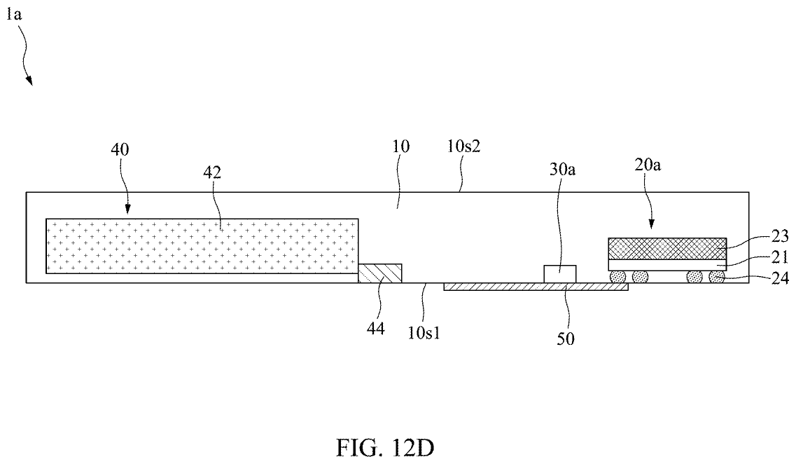

FIG. 12A, FIG. 12B, FIG. 12C, and FIG. 12D illustrate one or more stages of an example of a method for manufacturing an electronic device according to some arrangements of the present disclosure.

Referring to FIG. 12A, a carrier 80 may be provided. The carrier 80 may include a glass carrier, a ceramic carrier, a plastic carrier, an organic carrier, a silicon carrier, or other suitable carriers. The electronic package 20a, the electronic component 30a, and the energy storage component 40 may be attached to the top surface (not annotated) of the carrier 80.

Referring to FIG. 12B, the flexible encapsulant 10 may be formed over the carrier 80. The flexible encapsulant 10 may encapsulate the electronic package 20a, the electronic component 30a, and the energy storage component 40. The flexible encapsulant 10 may be formed by a molding technique, such as injection molding, compression molding, or transfer molding.

Referring to FIG. 12C, the carrier 80 may be removed. The surface 10s1 of the flexible encapsulant 10 may be exposed.

Referring to FIG. 12D, a conductive connection 50 may be formed under the surface 10s1 of the flexible encapsulant 10. As a result, an electronic device (e.g., the electronic device 1a as shown in FIG. 1) may be produced.

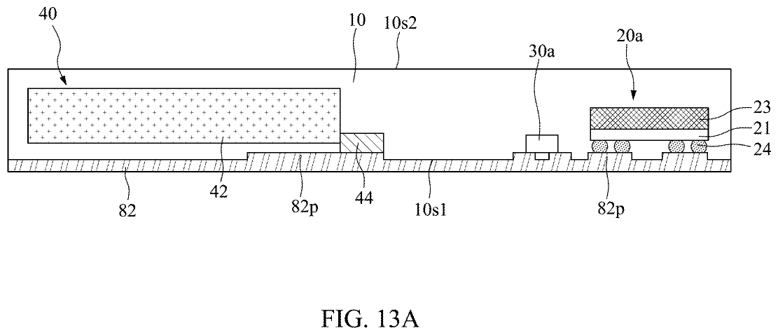

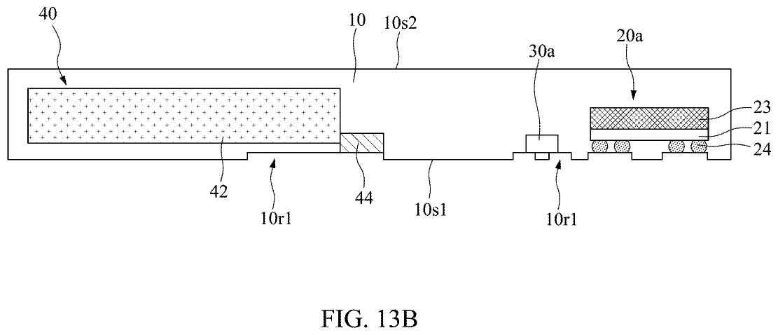

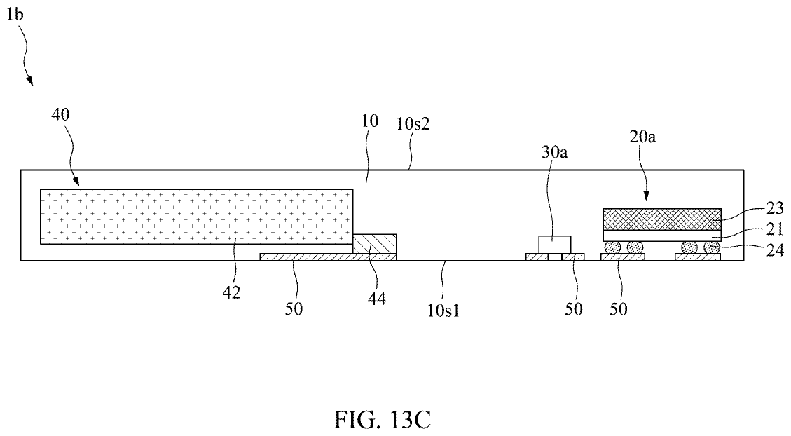

FIG. 13A, FIG. 13B, and FIG. 13C illustrate one or more stages of an example of a method for manufacturing an electronic device according to some arrangements of the present disclosure.

Referring to FIG. 13A, a carrier 82 may be provided. The carrier 82 may include a glass carrier, a ceramic carrier, a plastic carrier, or other suitable carriers. The carrier 82 may have a protruded portion 82p. The protruded portion 82p may be protruded from a top surface of the carrier 82. In some arrangements, the protruded portion 82p may be configured to define an encapsulant-defined region of a flexible encapsulant. The electronic package 20a, the electronic component 30a, and the energy storage component 40 may be attached to the protruded portion 82p of the carrier 80. The flexible encapsulant 10 may be formed on the carrier 82.

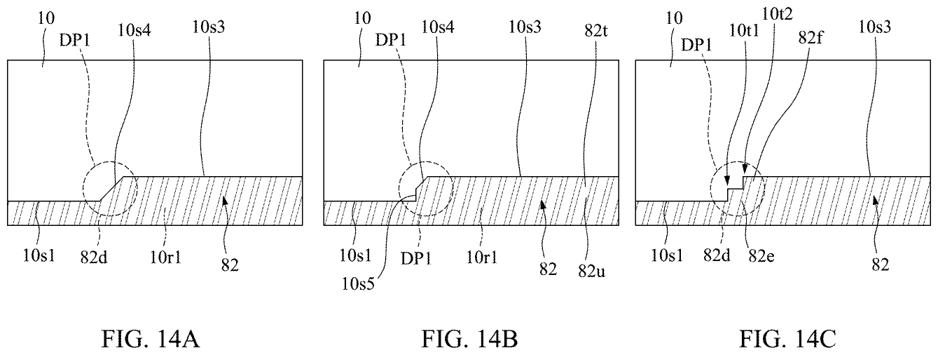

FIG. 14A is a partial enlarged view of FIG. 13A, in accordance with an arrangement of the present disclosure. In some arrangements, the carrier 82 may include a demoulding structure 82d, which makes the removal of the carrier 82 easier. In some arrangements, the demoulding structure 82d may include a draft angle or profiles facilitating the separation of the flexible encapsulant 10 from the carrier 82. In some arrangements, the demoulding structure 82d may include a tapered profile. In some arrangements, the demoulding structure 82d may define an obtuse angle, resulting in the surface 10s4 with a slanted surface. In some arrangements, the demoulding structure 82d may be tapered toward the flexible encapsulant 10. In some arrangements, the flexible encapsulant 10 may inherit the demoulding structure 82d of the carrier 80 as shown in FIG. 14A, and thereby exhibit the demoulding pattern DP1.

FIG. 14B is a partial enlarged view of FIG. 13A, in accordance with other arrangements of the present disclosure. In some arrangements, the demoulding structure 82d may have a uniform portion 82u with a uniform dimension (e.g., width or length) in a cross-sectional view and a tapered portion 82t over the uniform dimension. In some arrangements, the flexible encapsulant 10 may inherit the demoulding structure 82d of the carrier 80 as shown in FIG. 14B, and thereby exhibit the demoulding pattern DP1.

FIG. 14C is a partial enlarged view of FIG. 13A, in accordance with other arrangements of the present disclosure. In some arrangements, the demoulding structure 82d may include step profiles 82e and 82f, each of which may be composed of a vertical surface extending between two horizontal surfaces. In some arrangements, the flexible encapsulant 10 may inherit the demoulding structure 82d of the carrier 80 as shown in FIG. 14C, and thereby exhibit the demoulding pattern DP1 and.

Referring to FIG. 13B, the carrier 82 may be removed. The encapsulant-defined pattern 10r1 may be defined. The electrode 44 may be exposed by the encapsulant-defined pattern 10r1 of the flexible encapsulant 10. The terminal 24 may be exposed by the encapsulant-defined pattern 10r1 of the flexible encapsulant 10.

Referring to FIG. 13C, a conductive connection 50 may be formed within the encapsulant-defined pattern 10r1 of the flexible encapsulant 10. In some arrangements, a printing technique may be performed to form the conductive connection 50. In some arrangements, a conductive material may be filled within the encapsulant-defined pattern 10r1, and a curing technique (or a heat-treatment) may be performed on the conductive material to produce the conductive connection 50. In some arrangements, the profile of the conductive connection 50 may inherit the demoulding structure 82d of the carrier 82. As a result, an electronic device (e.g., the electronic device 1b as shown in FIG. 3A) may be produced.

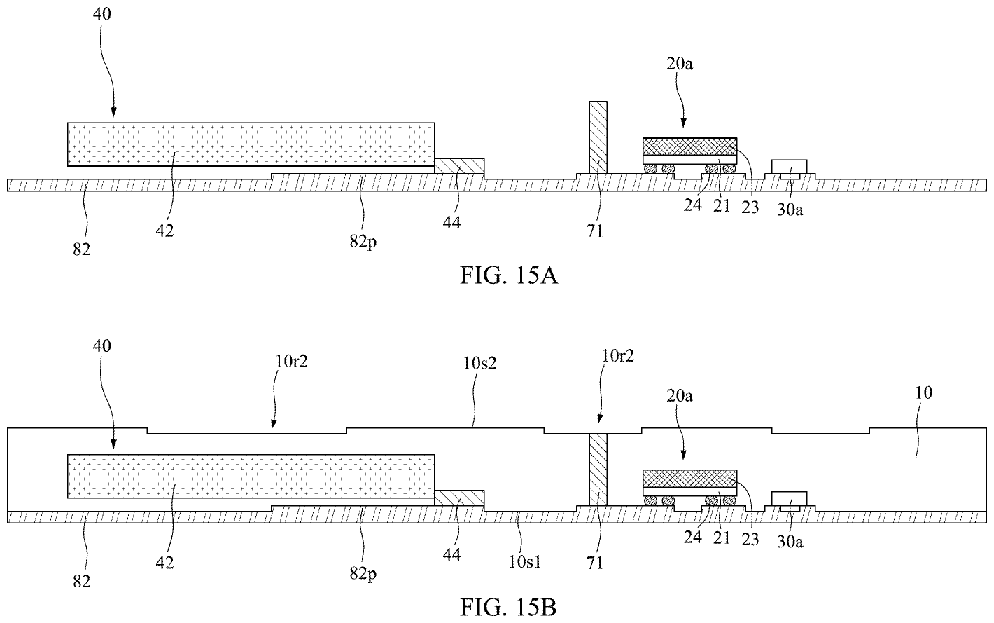

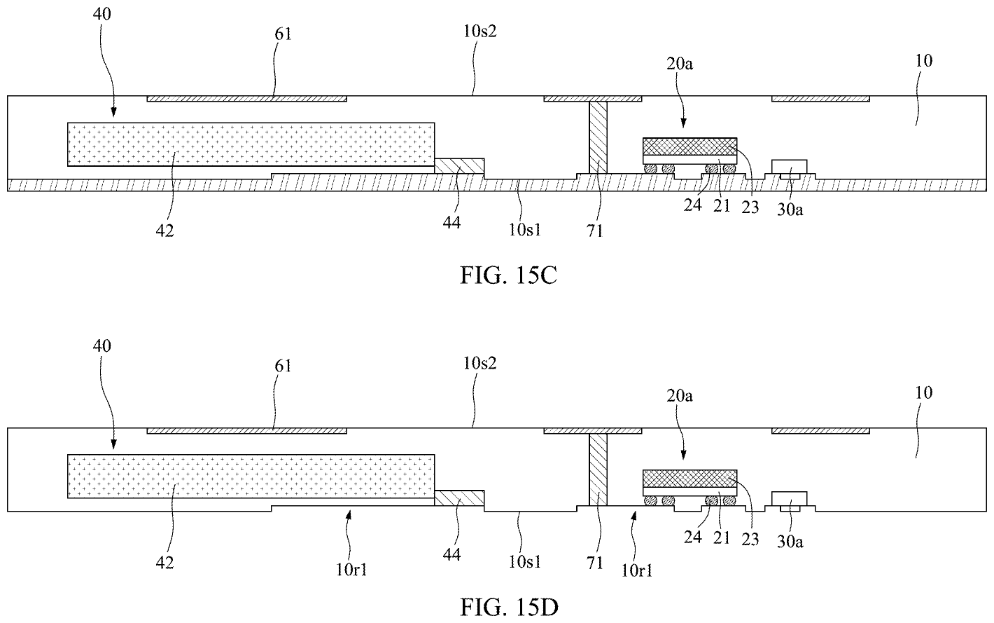

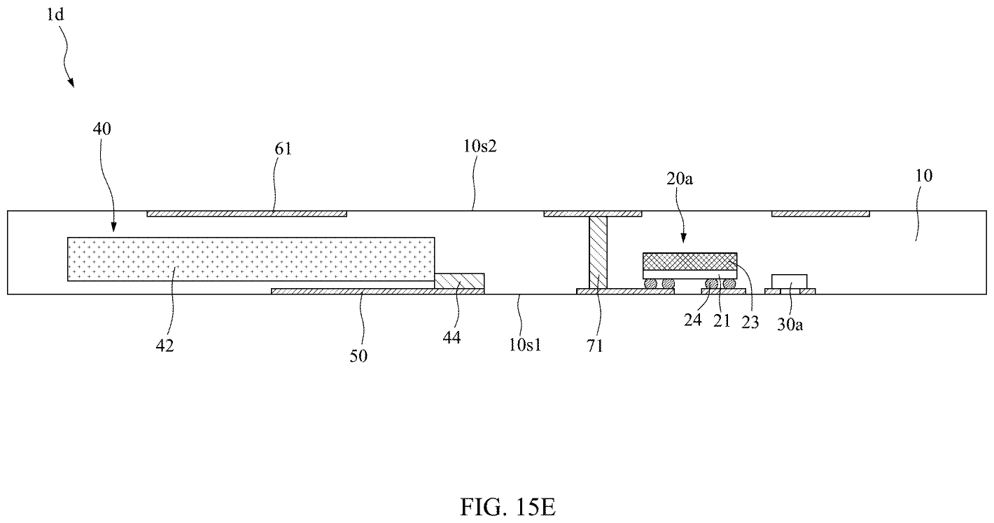

FIG. 15A, FIG. 15B, FIG. 15C, FIG. 15D, and FIG. 15E illustrate one or more stages of an example of a method for manufacturing an electronic device according to some arrangements of the present disclosure.

Referring to FIG. 15A, a carrier 82 may be provided. The carrier 82 may include a protruded portion 82p. The electronic package 20a, the electronic component 30a, and the energy storage component 40 may be attached to the protruded portion 82p of the carrier 80. The conductive pillar 71 may be formed over the carrier 82. The electronic package 20a, the electronic component 30a, and the energy storage component 40 may be attached to the protruded portion 82p of the carrier 80.

Referring to FIG. 15B, a flexible encapsulant 10 may be formed over the carrier 82. The flexible encapsulant 10 may encapsulate the electronic package 20, the electronic component 30a, the energy storage component 40, and the conductive pillar 71. In some arrangements, the flexible encapsulant 10 may define an encapsulant-defined pattern 10r2 recessed from the surface 10s2 of the flexible encapsulant 10. In some arrangements, a mold chase may be utilized. The mold chase may include a demoulding profile and a predetermined pattern. The flexible encapsulant 10 may inherit the profile of the mold chase. As a result, the flexible encapsulant 10 may exhibit the encapsulant-defined pattern 10r2 and a demolding profile as shown in FIG. 7B.

Referring to FIG. 15C, a conductive connection 61 may be formed within the encapsulant-defined pattern 10r2 of the flexible encapsulant 10. In some arrangements, a printing technique may be performed to form the conductive connection 61. In some arrangements, a conductive material may be filled within the encapsulant-defined pattern 10r2, and a curing technique (or a heat-treatment) may be performed on the conductive material to produce the conductive connection 62.

Referring to FIG. 15D, the carrier 82 may be removed. The encapsulant-defined pattern 10r1 may be defined and recessed from the surface 10s1 of the flexible encapsulant 10. The encapsulant-defined pattern 10r1 may inherit the pattern of the protruded portion 82p.

Referring to FIG. 15E, the conductive connection 50 may be formed within the encapsulant-defined pattern 10r1 of the flexible encapsulant 10. As a result, an electronic device (e.g., the electronic device 1d as shown in FIG. 7A) may be produced.

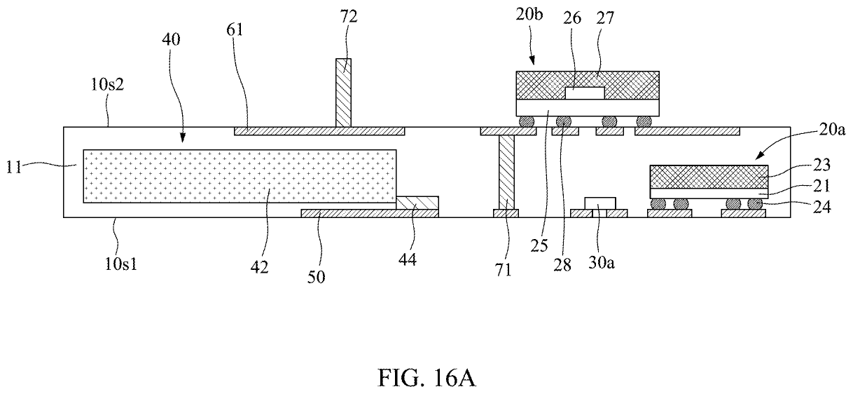

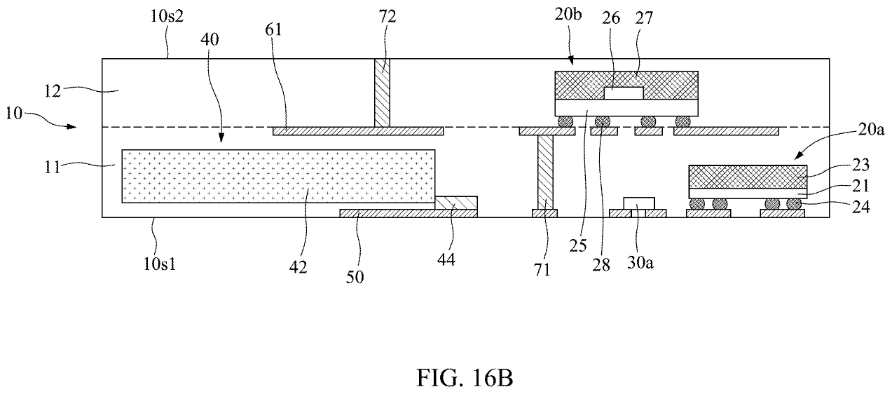

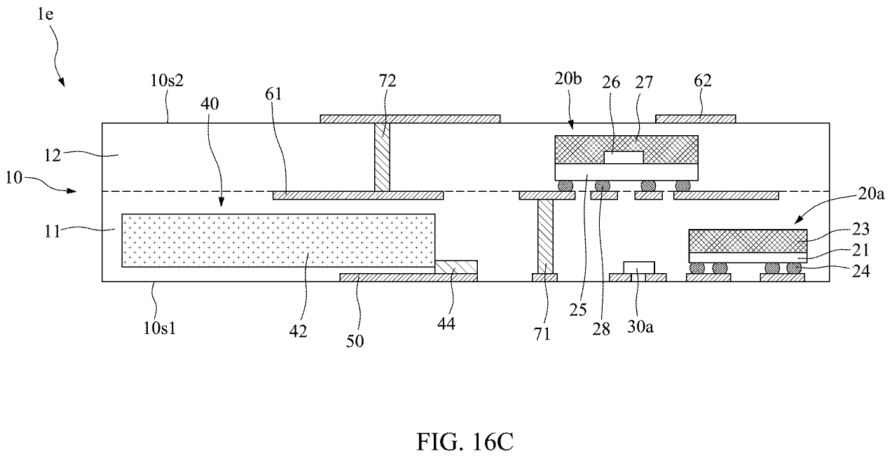

FIG. 16A, FIG. 16B, and FIG. 16C illustrate one or more stages of an example of a method for manufacturing an electronic device according to some arrangements of the present disclosure. The initial stage of the illustrated process is the same as, or similar to, the stage illustrated in FIG. 15A through FIG. 15E. FIG. 16A depicts a stage subsequent to that depicted in FIG. 15E.

Referring to FIG. 16A, an electronic package 20b may be attached to the conductive connection 61. A conductive pillar 72 may be attached to the conductive connection 61. The insulation layer 11 may be formed to encapsulate the electronic package 20b and the conductive pillar 72.

Referring to FIG. 16B, an insulation layer 12 may be formed over the insulation layer 11. The insulation layer 12 may encapsulate the conductive pillar 72 and the electronic package 20b. The insulation layer 11 and insulation layer 12 may define or exhibit the flexible encapsulant 10. The insulation layer 12 may be formed by a molding technique, such as injection molding, compression molding, or transfer molding.

Referring to FIG. 16C, a conductive connection 62 may be formed over the insulation layer 12. In some arrangements, a printing technique or other suitable techniques may be performed to form the conductive connection 62. As a result, an electronic device (e.g., the electronic device 1e as shown in FIG. 8) may be produced.

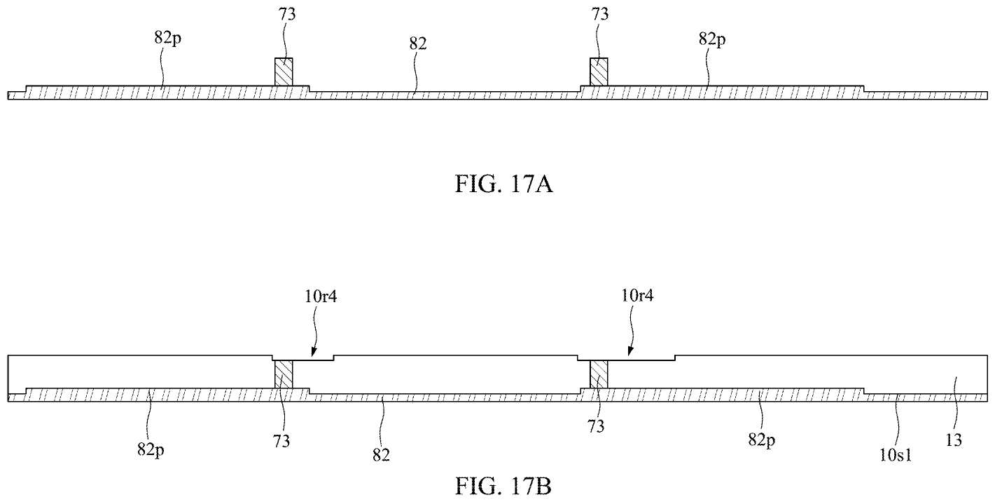

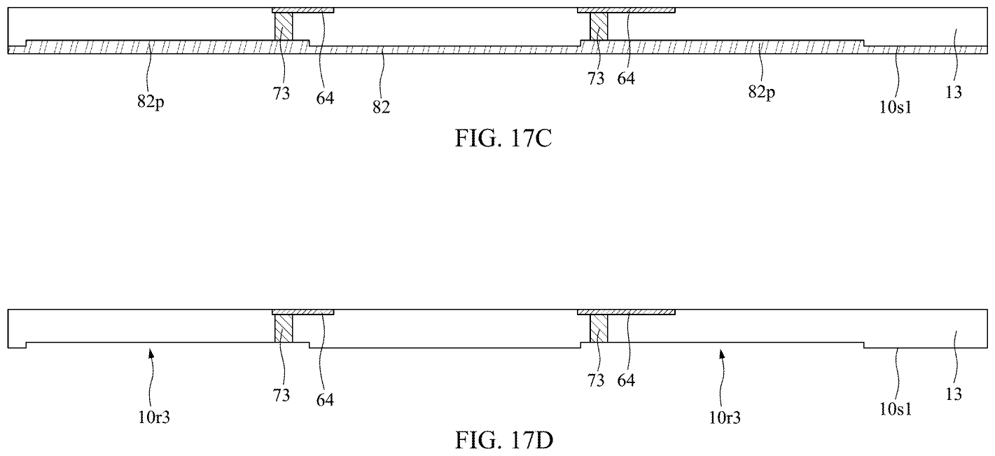

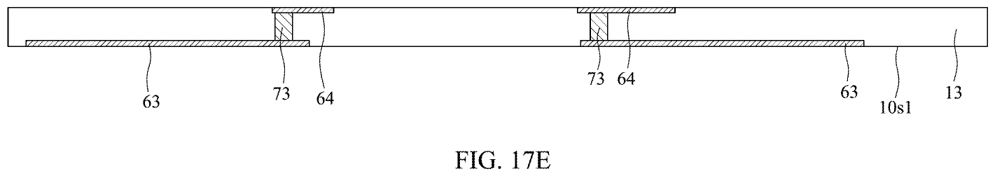

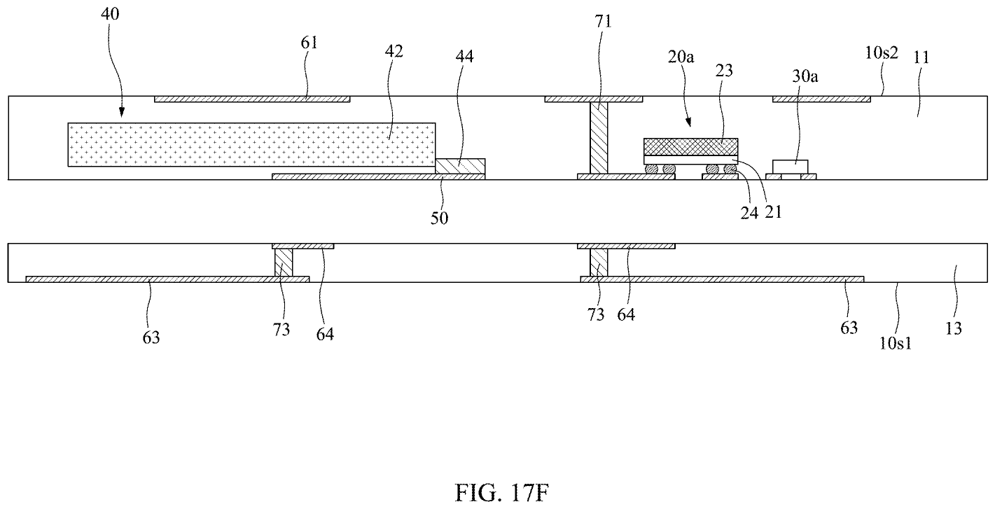

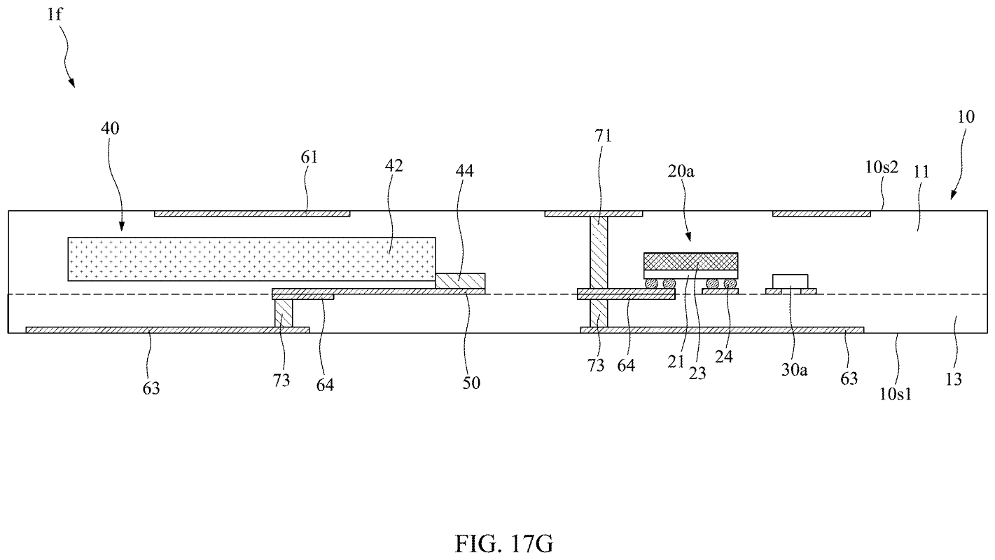

FIG. 17A, FIG. 17B, FIG. 17C, FIG. 17D, FIG. 17E, FIG. 17F, and FIG. 17G illustrate one or more stages of an example of a method for manufacturing an electronic device according to some arrangements of the present disclosure.

Referring to FIG. 17A, a carrier 82 may be provided. Conductive pillars 73 may be formed over the protruded portion 82p of the carrier 82.

Referring to FIG. 17B, an insulation layer 13 may be formed over the carrier 82. The insulation layer 13 may encapsulate the conductive pillar 73. The insulation layer 13 may be formed by a molding technique, such as injection molding, compression molding, or transfer molding. In some arrangements, a mold chase may be utilized. The mold chase may include a demoulding profile and a predetermined pattern. The insulation layer 13 may inherit the profile of the mold chase. As a result, the insulation layer 13 may define an encapsulant-defined pattern 10r4 exposing the conductive pillar 73.

Referring to FIG. 17C, a conductive connection 64 may be formed within the encapsulant-defined pattern 10r4. In some arrangements, a printing technique or other suitable techniques may be performed to form the conductive connection 64. The conductive connection 64 may inherit and conform to the profile of the encapsulant-defined pattern 10r4 of the flexible encapsulant 10. In some arrangements, a conductive material may be filled within the encapsulant-defined pattern 10r4, and a curing technique (or a heat-treatment) may be performed on the conductive material to produce the conductive connection 64.

Referring to FIG. 17D, the carrier 82 may be removed. The encapsulant-defined pattern 10r3 may be defined and recessed from the bottom surface of the insulation layer 13. The encapsulant-defined pattern 10r3 may inherit the pattern of the protruded portion 82p.

Referring to FIG. 17E, a conductive connection 63 may be formed within the encapsulant-defined pattern 10r3. In some arrangements, a printing technique or other suitable techniques may be performed to form the conductive connection 63. In some arrangements, a conductive material may be filled within the encapsulant-defined pattern 10r3, and a curing technique (or a heat-treatment) may be performed on the conductive material to produce the conductive connection 63. The conductive connection 63 may inherit and conform to the profile of the encapsulant-defined pattern 10r3.

Referring to FIG. 17F, the structure (e.g., the electronic device 1d) as shown in FIG. 15E may be provided.

Referring to FIG. 17G, the insulation layer 11 may be attached to the insulation layer 13. The conductive connection 50 may be attached to the conductive connection 64. The insulation layer 11 and insulation layer 13 may define or exhibit the flexible encapsulant 10. As a result, an electronic device (e.g., the electronic device 1f as shown in FIG. 9) may be produced.

In other arrangements, after the stage of FIG. 17E, the electronic package 20a, the electronic component 30a, and the energy storage component 40 may be attached to the conductive connection 64. The conductive pillar 71 may be formed over the conductive connection 64. Next, an insulation layer 11 may be formed over the insulation layer 13. The insulation layer 11 defines or exhibits an encapsulant-defined pattern 10r2 adjacent to the top surface of the insulation layer 11. Finally, the conductive connection 61 may be formed within the encapsulant-defined pattern 10r2, which thereby produces the electronic device 1f.

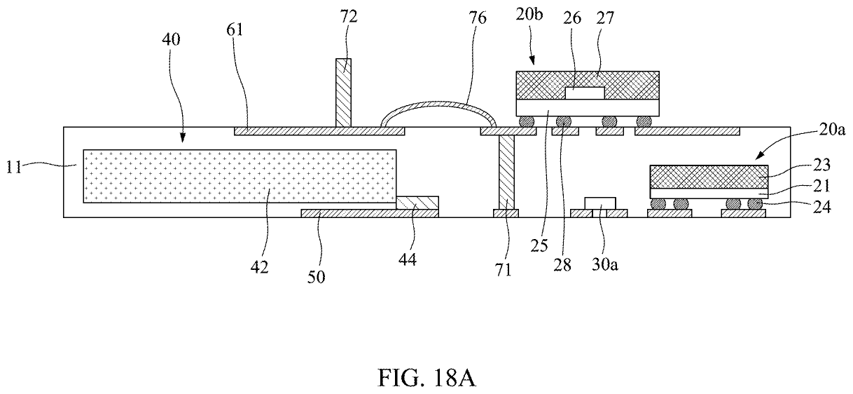

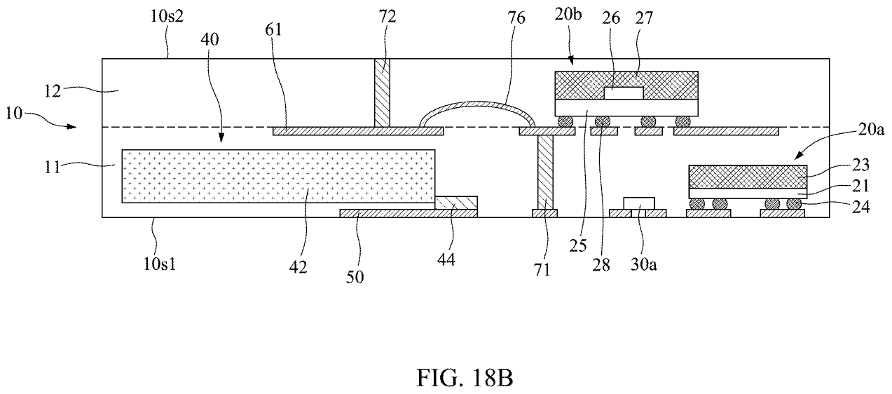

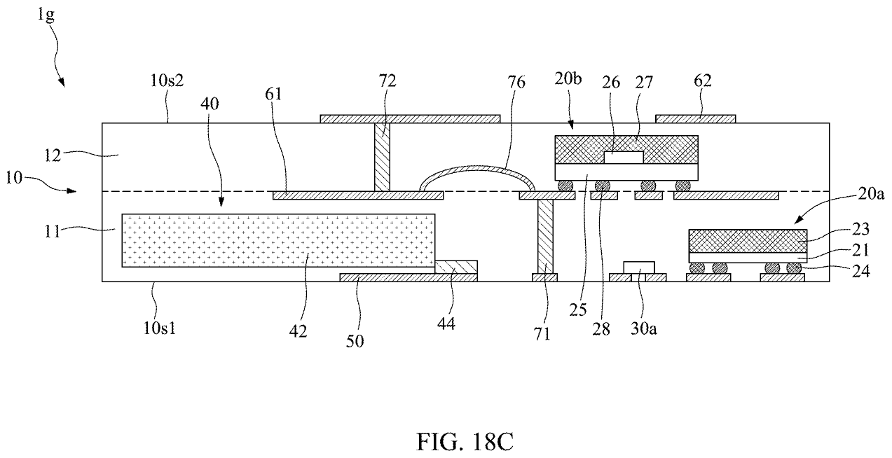

FIG. 18A, FIG. 18B, and FIG. 18C illustrate one or more stages of an example of a method for manufacturing an electronic device according to some arrangements of the present disclosure. The initial stage of the illustrated process is the same as, or similar to, the stage illustrated in FIG. 15A through FIG. 15E. FIG. 18A depicts a stage subsequent to that depicted in FIG. 15E.

Referring to FIG. 18A, an electronic package 20b may be attached to the conductive connection 61. A conductive pillar 72 may be attached to the conductive connection 61. A conductive wire 76 may be formed over the conductive connection 61.

Referring to FIG. 18B, an insulation layer 12 may be formed over the insulation layer 11. The insulation layer 12 may encapsulate the conductive pillar 72, the electronic package 20b, and the conductive wire 76. The insulation layer 11 and insulation layer 12 may define or exhibit the flexible encapsulant 10.

Referring to FIG. 18C, a conductive connection 62 may be formed over the insulation layer 12. In some arrangements, a printing technique or other suitable techniques may be performed to form the conductive connection 62. As a result, an electronic device (e.g., the electronic device 1g as shown in FIG. 10) may be produced.

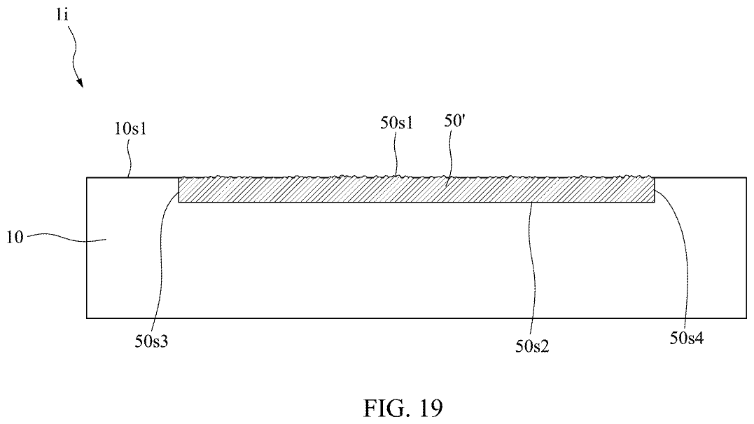

FIG. 19 is a cross-sectional view of an electronic device 1i, in accordance with an arrangement of the present disclosure. The electronic device 1i may include a conductive connection 50′. The material and the location of the conductive connection 50′ may be the same as or similar to those of the conductive connection 50. Further, the conductive connection 50′ may include demoulding pattern as shown in FIG. 4A to FIG. 4C. The conductive connection 50′ may include a surface 50s3 extending between the surfaces 50s1 and 50s2 and a surface 50s4 opposite to the surface 50s3. In some arrangements, the conductive connection 50′ may include conductive particles (e.g., silver particles or other conductive materials). The particles may be exposed by the surface 50s1 of the conductive connection 50′. Thus, the surface 50s1 may be relatively rough. In some arrangements, the roughness of the surface 50s1 may be greater than that of the surface 10s1.

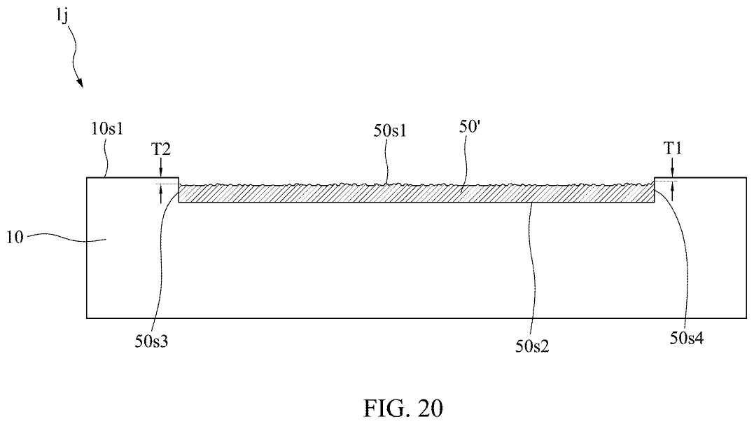

FIG. 20 is a cross-sectional view of an electronic device 1j, in accordance with an arrangement of the present disclosure. In some arrangements, the conductive connection 50′ may be recessed from the surface 10s1 of the flexible encapsulant 10. In some arrangements, the surface 10s1 may be coated or formed with a conductive paste or other suitable materials. A scraper or other suitable components may be utilized to apply pressure to the surface 10s1, causing the conductive paste to fill the encapsulant-defined pattern (e.g., the encapsulant-defined pattern 10r1) to form the conductive connection 50′. In some conditions, the scraper may exert pressure on the conductive paste, resulting in the conductive connection 50′ being recessed from the surface 10s1. In some arrangements, the conductive connection 50′ may have different levels abutting the surfaces 50s3 and 50s4. A distance T1 may be defined by the surface 50s1 of the conductive connection 50′ and the surface 10s1 of the flexible encapsulant 10 at the surface 50s4 (or side). A distance T2 may be defined by the surface 50s1 of the conductive connection 50′ and the surface 10s1 of the flexible encapsulant 10 at the surface 50s3 (or side). In some arrangements, the distance T1 may be different from the distance T2.

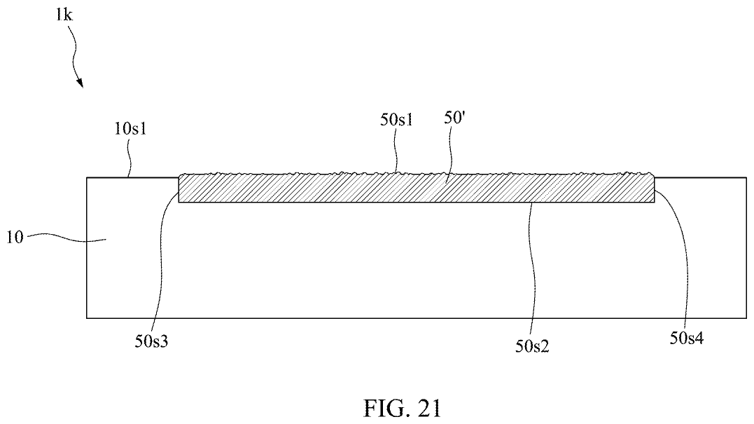

FIG. 21 is a cross-sectional view of an electronic device 1k, in accordance with an arrangement of the present disclosure. In some arrangements, the surface 50s1 of the conductive connection 50′ may be protruded from the surface 10s1 of the flexible encapsulant 10.

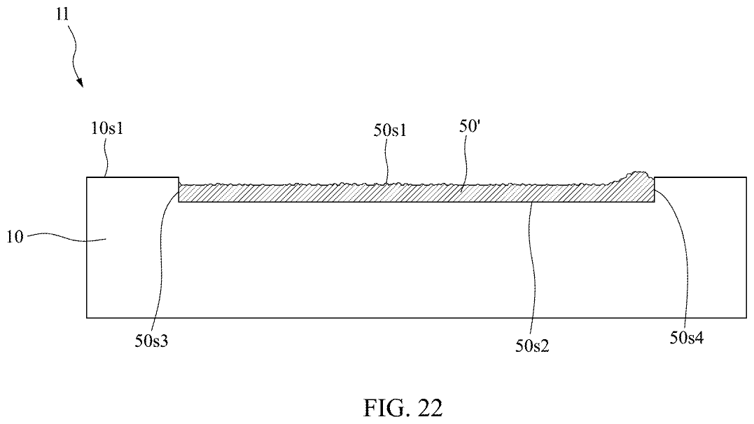

FIG. 22 is a cross-sectional view of an electronic device 1l, in accordance with an arrangement of the present disclosure. In some arrangements, a portion of the surface 50s1 of the conductive connection 50′ may be higher than the surface 10s1 of the flexible encapsulant 10, and an another portion of the surface 50s1 of the conductive connection 50′ may be lower than the surface 10s1 of the flexible encapsulant 10.

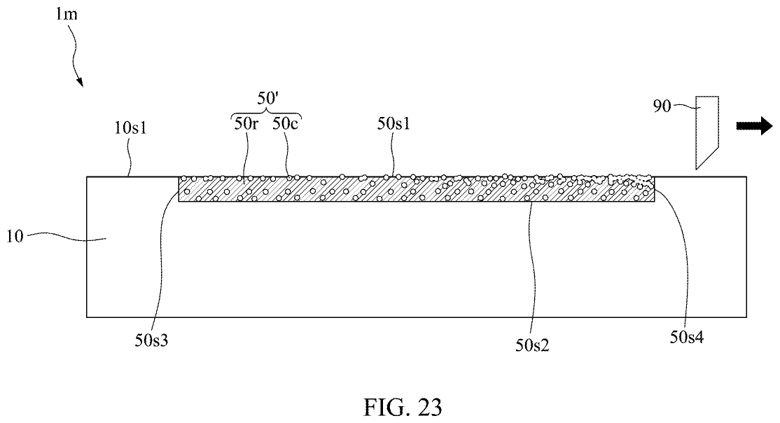

FIG. 23 is a cross-sectional view of an electronic device 1m, in accordance with an arrangement of the present disclosure. In some arrangements, the conductive connection 50′ may include a filler 50r and conductive particles 50c within the filler 50r. The filler 50r may include resin or other suitable materials. The conductive particle 50c may include silver, gold, titanium, copper, aluminum, or other suitable materials. When a scraper moves along a direction from the surface 50s3 toward the surface 50s4, the conductive particles 50c which abut the surface 50s1 may be distributed non-uniformly. For example, the density of the conductive particles 50c abutting the surface 50s4 may be greater than that abutting the surface 50s3. In some arrangements, the conductive particles 50c abutting the surface 50s2 may be distributed more uniformly compared to the conductive particles 50c abutting the surface 50s1.

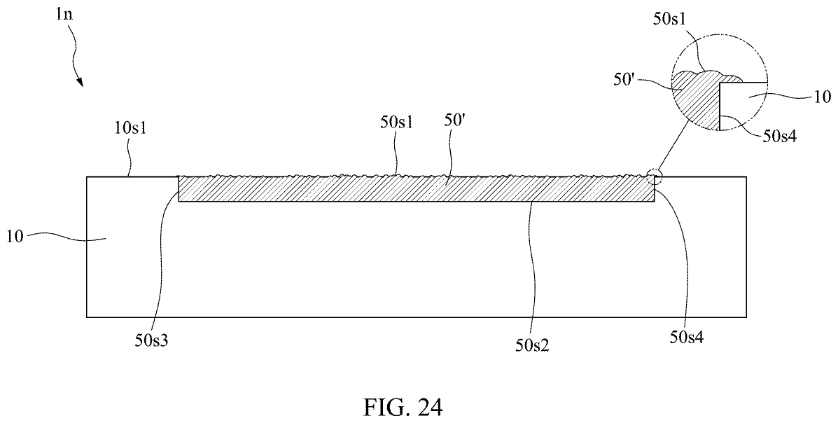

FIG. 24 is a cross-sectional view of an electronic device 1n, in accordance with an arrangement of the present disclosure. In some arrangements, a portion of the conductive connection 50′ may be disposed on the surface 10s1 of the flexible encapsulant 10.

In some arrangements, an electronic device includes a flexible encapsulant, a first electronic component, and a first conductive connection. The flexible encapsulant has a first encapsulant-defined pattern. The first electronic component is disposed within the flexible encapsulant. The first electronic component includes a terminal exposed by the first encapsulant-defined pattern. The first conductive connection is disposed within the first encapsulant-defined pattern and electrically connected to the terminal of the first electronic component.

In some arrangements, the flexible encapsulant has a bottom surface substantially aligned with a bottom surface of the first conductive connection. In some arrangements, the first encapsulant-defined pattern is recessed from the bottom surface of the flexible encapsulant. In some arrangements, the first encapsulant-defined pattern has a demoulding pattern. In some arrangements, the first conductive connection conforms to the demoulding pattern of the first encapsulant-defined pattern. In some arrangements, the flexible encapsulant has a bottom surface and a top surface opposite to the bottom surface, and the first conductive connection is adjacent to the bottom surface and tapered toward the top surface of the flexible encapsulant. In some arrangements, the first conductive connection comprises a step profile within the first encapsulant-defined pattern. In some arrangements, the flexible encapsulant has a second encapsulant-defined pattern at a level different from a level of the first encapsulant-defined pattern, and the electronic device further comprises a second conductive connection disposed within the second encapsulant-defined pattern. In some arrangements, the second encapsulant-defined pattern has a demoulding pattern. In some arrangements, the flexible encapsulant has a bottom surface adjacent to the first encapsulant-defined pattern and a top surface adjacent to the second encapsulant-defined pattern. In some arrangements, a top surface of the second conductive connection is substantially aligned with the top surface of the flexible encapsulant. In some arrangements, the second conductive connection is embedded within the flexible encapsulant. In some arrangements, the second conductive connection is tapered toward the first conductive connection, and the first conductive connection is tapered toward the second conductive connection. In some arrangements, a power storage component electrically connected to the first electronic component by the first conductive connection. In some arrangements, a second electronic component electrically connected to the second conductive connection, wherein a projection of the second electronic component onto a bottom surface of the flexible encapsulant is closer to a projection of the first electronic component onto the bottom surface of the flexible encapsulant than to a projection of the power storage component onto the bottom surface of the flexible encapsulant. In some arrangements, a second electronic component vertically overlapping the first electronic component.

In some arrangements, an electronic device includes a flexible encapsulant, a first conductive connection, and an electronic component. The flexible encapsulant has a bottom surface. The flexible encapsulant has a first demoulding pattern adjacent to the bottom surface. The first conductive connection is adjacent to the bottom surface. The first conductive connection is at least partially embedded within the flexible encapsulant and conformally to the first demoulding pattern. The electronic component is within the flexible encapsulant and electrically connected to the first conductive connection.

In some arrangements, the first conductive connection has a bottom surface substantially aligned with the bottom surface of the flexible encapsulant. In some arrangements, the first conductive connection has a top surface opposite to the bottom surface, and a length of the top surface is less than a length of the bottom surface in a cross-sectional view. In some arrangements, the electronic component is attached to the first conductive connection by a flip-chip technique. In some arrangements, a power storage component disposed adjacent to the bottom surface of the flexible encapsulant and electrically connected to the first conductive connection, wherein the first conductive connection has a first circuit density abutting the electronic component and a second circuit density, greater than the first circuit density, abutting the power storage component. In some arrangements, the flexible encapsulant has a second demoulding pattern spaced apart from the bottom surface, and the electronic device comprises a second conductive connection conforming to the second demoulding pattern. In some arrangements, the second conductive connection has a top surface and a bottom surface opposite to the top surface, and a length of the top surface of the second conductive connection is greater than a length of the bottom surface of the second conductive connection in a cross-sectional view. In some arrangements, the second demoulding pattern of the flexible encapsulant is spaced apart from a top surface of the flexible encapsulant. In some arrangements, the first conductive connection comprises conductive paste or conductive ink.

In some arrangements, a method of manufacturing an electronic device includes: providing a carrier having a pattern; forming an encapsulant to the carrier; removing the carrier, wherein the encapsulant has a first predetermined pattern, corresponding to the pattern of the carrier, at a first surface of the encapsulant; and forming a conductive connection within the first predetermined pattern of the encapsulant.

In some arrangements, the pattern comprises a protruded portion protruded from the carrier. In some arrangements, the method includes attaching a terminal of an electronic component to the protruded portion of the carrier. In some arrangements, the encapsulant is formed by an injection molding technique. In some arrangements, the encapsulant has a second predetermined pattern at a second surface opposite to the first surface. In some arrangements, the protruded portion comprises a demoulding pattern.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or

At 0 circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, two numerical values can be deemed to be “substantially” the same or equal if a difference between the values is less than or equal to +10% of an average of the values, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a pliable encapsulant having a first predetermined pattern;
a first electronic component disposed within the pliable encapsulant, wherein the first electronic component comprises a terminal exposed by the first predetermined pattern; and
a conductive connection disposed within the first predetermined pattern and electrically connected to the terminal of the first electronic component.

2. The electronic device of claim 1, wherein the first predetermined pattern is tapered from a bottom surface of the pliable encapsulant.

3. The electronic device of claim 1, wherein a roughness of a bottom surface of the conductive connection is greater than a roughness of a bottom surface of the pliable encapsulant.

4. The electronic device of claim 1, wherein a first distance between a bottom surface of the conductive connection and a bottom surface of the pliable encapsulant at a first side of the conductive connection is different from a second distance between the bottom surface of the conductive connection and the bottom surface of the pliable encapsulant at a second side, opposite to the first side, of the conductive connection.

5. The electronic device of claim 1, wherein the first predetermined pattern has a first width, along a first direction, abutting a bottom surface of the pliable encapsulant and a second width, along the first direction, far away from the bottom surface of the pliable encapsulant, and the first width is greater than the second width.

6. The electronic device of claim 5, wherein the first predetermined pattern has a third width, along a second direction substantially perpendicular to the first direction, abutting the bottom surface of the pliable encapsulant and a fourth width, along the second direction, far away from the bottom surface of the pliable encapsulant, and the third width is greater than the fourth width.

7. The electronic device of claim 5, wherein the first predetermined pattern has a profile slanted with respect to the bottom surface of the pliable encapsulant.

8. The electronic device of claim 5, wherein the first predetermined pattern has a step profile.

9. The electronic device of claim 1, wherein the conductive connection has a profile tapered toward a top surface of the pliable encapsulant.

10. The electronic device of claim 1, further comprising:
a second electronic component encapsulated by the pliable encapsulant, wherein the conductive connection electrically connects the first electronic component and the second electronic component.

11. An electronic device, comprising:
a pliable encapsulant having a first surface and a second surface opposite to the first surface;
a first conductive connection recessed from the second surface; and
a second conductive connection recessed from the first surface and electrically connected to the first conductive connection.

12. The electronic device of claim 11, further comprising:
a first electronic component encapsulated by the pliable encapsulant and electrically connected to the first conductive connection.

13. The electronic device of claim 12, further comprising:
a second electronic component disposed on the pliable encapsulant and electrically connected to the second conductive connection.

14. The electronic device of claim 13, wherein the first electronic component at least partially overlaps the second electronic component in a substantially vertical direction.

15. The electronic device of claim 11, further comprising:
a conductive element encapsulated by the pliable encapsulant and connected to the first conductive connection and the second conductive connection.

16. The electronic device of claim 11, wherein the first conductive connection is tapered along a direction different from that of the second conductive connection.

17. A method of manufacturing an electronic device, comprising:
providing a first electronic component and an encapsulant encapsulating the first electronic component;
forming a first predetermined pattern defined by the encapsulant; and
forming a first conductive connection within the first predetermined pattern of the encapsulant to be electrically connected to the first electronic component.

18. The method of claim 17, further comprising:
providing a second electronic component, wherein the encapsulant encapsulates the second electronic component, and the first conductive connection electrically connects the first electronic component to the second electronic component.

19. The method of claim 18, further comprising:
forming a second predetermined pattern, opposite to the first predetermined pattern, defined by the encapsulant; and
forming a second conductive connection within the second predetermined pattern of the encapsulant.

20. The method of claim 19, further comprising:
providing a conductive element electrically connected to the first conductive connection and the second conductive connection.
